(19) United States
(12) Patent Application Publication
(10) Pub. No.: US 2026/0089046 A1
(43) Pub. Date: Mar. 26, 2026

(54) ENERGY-BASED ARITHMETIC CODING FOR PROBABILISTIC AMPLITUDE SHAPING

(71) Applicant: QUALCOMM Incorporated, San Diego, CA (US)

(72) Inventors: Wei LIU, Beijing (CN); Thomas Joseph RICHARDSON, South Orange, NJ (US); Liangming WU, Beijing (CN); Changlong XU, Beijing (CN); Ori SHENTAL, Marlboro, NJ (US); Hao XU, Beijing (CN)

(21) Appl. No.: 19/112,843

(22) PCT Filed: Nov. 8, 2022
(86) PCT No.: PCT/CN2022/130534

§ 371 Date: Mar. 18, 2025

(51) Int. Cl. H04L 27/34; H03M 13/07

(52) U.S. Cl. CPC H04L 27/3494; H03M 13/07; H04L 27/3405

(57) ABSTRACT

Various aspects of the present disclosure generally relate to wireless communication. In some aspects, a transmitting node may obtain a k-bit sequence of information bits. The transmitting node may encode the k-bit sequence to an output sequence that corresponds to a length-n symbol sequence in a set of symbol sequences of length n and over an alphabet Aₘ in accordance with a first phase of energy-based arithmetic coding for probabilistic amplitude shaping (PAS) and a second phase of energy-based arithmetic coding for PAS. The transmitting node may perform, to a receiving node, a transmission based at least in part on the length-n symbol sequence. Numerous other aspects are described.

### FIELD OF THE DISCLOSURE

Aspects of the present disclosure generally relate to wireless communication and to techniques and apparatuses for energy-based arithmetic coding for probabilistic amplitude shaping (PAS).

### BACKGROUND

Wireless communication systems are widely deployed to provide various telecommunication services such as telephony, video, data, messaging, and broadcasts. Typical wireless communication systems may employ multiple-access technologies capable of supporting communication with multiple users by sharing available system resources (e.g., bandwidth, transmit power, or the like). Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, time division synchronous code division multiple access (TD-SCDMA) systems, and Long Term Evolution (LTE). LTE/LTE-Advanced is a set of enhancements to the Universal Mobile Telecommunications System (UMTS) mobile standard promulgated by the Third Generation Partnership Project (3GPP).

A wireless network may include one or more network nodes that support communication for wireless communication devices, such as a user equipment (UE) or multiple UEs. A UE may communicate with a network node via downlink communications and uplink communications. “Downlink” (or “DL”) refers to a communication link from the network node to the UE, and “uplink” (or “UL”) refers to a communication link from the UE to the network node. Some wireless networks may support device-to-device communication, such as via a local link (e.g., a sidelink (SL), a wireless local area network (WLAN) link, and/or a wireless personal area network (WPAN) link, among other examples).

The above multiple access technologies have been adopted in various telecommunication standards to provide a common protocol that enables different UEs to communicate on a municipal, national, regional, and/or global level. New Radio (NR), which may be referred to as 5G, is a set of enhancements to the LTE mobile standard promulgated by the 3GPP. NR is designed to better support mobile broadband internet access by improving spectral efficiency, lowering costs, improving services, making use of new spectrum, and better integrating with other open standards using orthogonal frequency division multiplexing (OFDM) with a cyclic prefix (CP) (CP-OFDM) on the downlink, using CP-OFDM and/or single-carrier frequency division multiplexing (SC-FDM) (also known as discrete Fourier transform spread OFDM (DFT-s-OFDM)) on the uplink, as well as supporting beamforming, multiple-input multiple-output (MIMO) antenna technology, and carrier aggregation. As the demand for mobile broadband access continues to increase, further improvements in LTE, NR, and other radio access technologies remain useful.

### SUMMARY

In some implementations, an apparatus for wireless communication at a transmitting node includes a memory; and one or more processors, coupled to the memory, configured to: obtain a k-bit sequence of information bits; encode the k-bit sequence to an output sequence that corresponds to a length-n symbol sequence in a set of symbol sequences of length n and over an alphabet [symbol] ₘ in accordance with a first phase of energy-based arithmetic coding for probabilistic amplitude shaping (PAS) and a second phase of energy-based arithmetic coding for PAS, wherein: the first phase of energy-based arithmetic coding for PAS is associated with determining an energy E associated with the length-n symbol sequence; and the second phase of energy-based arithmetic coding for PAS is associated with determining the length-n symbol sequence based at least in part on multiple iterations, wherein each iteration is associated with deriving energies of subsequences of the length-n symbol sequence; and perform, to a receiving node, a transmission based at least in part on the length-n symbol sequence.

In some implementations, a method of wireless communication performed by a transmitting node includes obtaining a k-bit sequence of information bits; encoding the k-bit sequence to an output sequence that corresponds to a length-n symbol sequence in a set of symbol sequences of length n and over an alphabet [symbol] ₘ in accordance with a first phase of energy-based arithmetic coding for PAS and a second phase of energy-based arithmetic coding for PAS, wherein: the first phase of energy-based arithmetic coding for PAS is associated with determining an energy E associated with the length-n symbol sequence; and the second phase of energy-based arithmetic coding for PAS is associated with determining the length-n symbol sequence based at least in part on multiple iterations, wherein each iteration is associated with deriving energies of subsequences of the length-n symbol sequence; and performing, to a receiving node, a transmission based at least in part on the length-n symbol sequence.

In some implementations, a non-transitory computer-readable medium storing a set of instructions for wireless communication includes one or more instructions that, when executed by one or more processors of a transmitting node, cause the transmitting node to: obtain a k-bit sequence of information bits; encode the k-bit sequence to an output sequence that corresponds to a length-n symbol sequence in a set of symbol sequences of length n and over an alphabet [symbol] ₘ in accordance with a first phase of energy-based arithmetic coding for PAS and a second phase of energy-based arithmetic coding for PAS, wherein: the first phase of energy-based arithmetic coding for PAS is associated with determining an energy E associated with the length-n symbol sequence; and the second phase of energy-based arithmetic coding for PAS is associated with determining the length-n symbol sequence based at least in part on multiple iterations, wherein each iteration is associated with deriving energies of subsequences of the length-n symbol sequence; and perform, to a receiving node, a transmission based at least in part on the length-n symbol sequence.

In some implementations, an apparatus for wireless communication includes means for obtaining a k-bit sequence of information bits; means for encoding the k-bit sequence to an output sequence that corresponds to a length-n symbol sequence in a set of symbol sequences of length n and over an alphabet [symbol] ₘ in accordance with a first phase of energy-based arithmetic coding for PAS and a second phase of energy-based arithmetic coding for PAS, wherein: the first phase of energy-based arithmetic coding for PAS is associated with determining an energy E associated with the length-n symbol sequence; and the second phase of energy-based arithmetic coding for PAS is associated with determining the length-n symbol sequence based at least in part on multiple iterations, wherein each iteration is associated with deriving energies of subsequences of the length-n symbol sequence; and means for performing, to a receiving node, a transmission based at least in part on the length-n symbol sequence.

Aspects generally include a method, apparatus, system, computer program product, non-transitory computer-readable medium, user equipment, base station, network entity, network node, wireless communication device, and/or processing system as substantially described herein with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages, will be better understood from the following description when considered in connection with the accompanying figures. Each of the figures is provided for the purposes of illustration and description, and not as a definition of the limits of the claims.

While aspects are described in the present disclosure by illustration to some examples, those skilled in the art will understand that such aspects may be implemented in many different arrangements and scenarios. Techniques described herein may be implemented using different platform types, devices, systems, shapes, sizes, and/or packaging arrangements. For example, some aspects may be implemented via integrated chip embodiments or other non-module-component based devices (e.g., end-user devices, vehicles, communication devices, computing devices, industrial equipment, retail/purchasing devices, medical devices, and/or artificial intelligence devices). Aspects may be implemented in chip-level components, modular components, non-modular components, non-chip-level components, device-level components, and/or system-level components. Devices incorporating described aspects and features may include additional components and features for implementation and practice of claimed and described aspects. For example, transmission and reception of wireless signals may include one or more components for analog and digital purposes (e.g., hardware components including antennas, radio frequency (RF) chains, power amplifiers, modulators, buffers, processors, interleavers, adders, and/or summers). It is intended that aspects described herein may be practiced in a wide variety of devices, components, systems, distributed arrangements, and/or end-user devices of varying size, shape, and constitution.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating an example of a wireless network, in accordance with the present disclosure.

FIG. 2 is a diagram illustrating an example of a network node in communication with a user equipment (UE) in a wireless network, in accordance with the present disclosure.

FIG. 3 is a diagram illustrating an example disaggregated base station architecture, in accordance with the present disclosure.

FIG. 4 is a diagram illustrating an example of a probabilistic amplitude shaping (PAS) architecture, in accordance with the present disclosure.

FIG. 5 is a diagram illustrating an example of sphere shaping, in accordance with the present disclosure.

FIG. 6 is a diagram illustrating an example of symbol sequences over an alphabet, in accordance with the present disclosure.

FIG. 7 is a diagram illustrating an example associated with energy-based arithmetic coding for PAS, in accordance with the present disclosure.

FIG. 8 is a diagram illustrating an example process associated with energy-based arithmetic coding for PAS, in accordance with the present disclosure.

FIG. 9 is a diagram of an example apparatus for wireless communication, in accordance with the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Several aspects of telecommunication systems will now be presented with reference to various apparatuses and techniques. These apparatuses and techniques will be described in the following detailed description and illustrated in the accompanying drawings by various blocks, modules, components, circuits, steps, processes, algorithms, or the like (collectively referred to as “elements”). These elements may be implemented using hardware, software, or combinations thereof. Whether such elements are implemented as hardware or software depends upon the particular application and design constraints imposed on the overall system.

While aspects may be described herein using terminology commonly associated with a 5G or New Radio (NR) radio access technology (RAT), aspects of the present disclosure can be applied to other RATs, such as a 3G RAT, a 4G RAT, and/or a RAT subsequent to 5G (e.g., 6G).

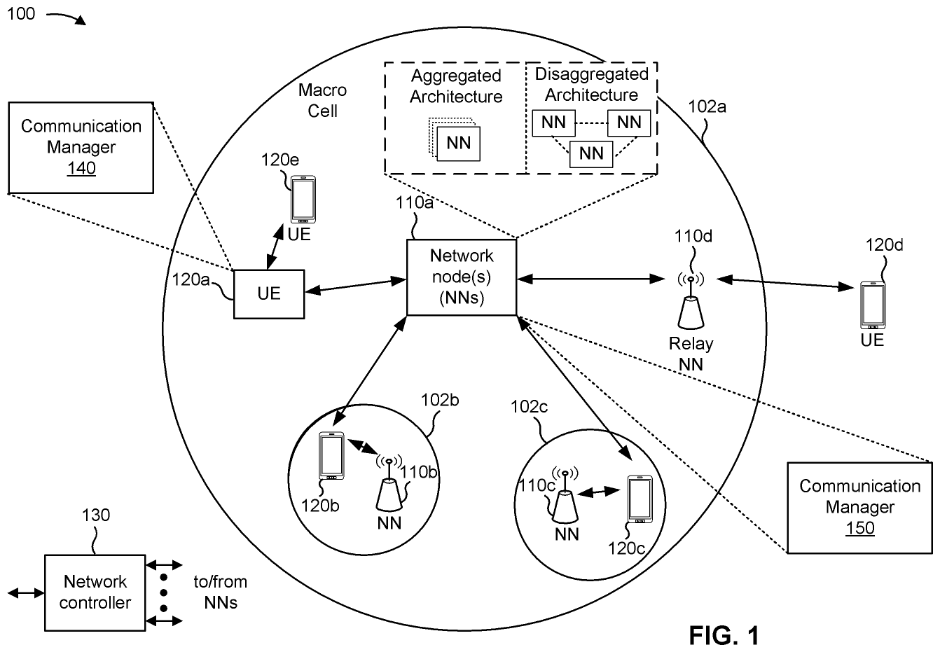

FIG. 1 is a diagram illustrating an example of a wireless network 100, in accordance with the present disclosure. The wireless network 100 may be or may include elements of a 5G (e.g., NR) network and/or a 4G (e.g., Long Term Evolution (LTE)) network, among other examples. The wireless network 100 may include one or more network nodes 110 (shown as a network node 110a, a network node 110b, a network node 110c, and a network node 110d), a user equipment (UE) 120 or multiple UEs 120 (shown as a UE 120a, a UE 120b, a UE 120c, a UE 120d, and a UE 120e), and/or other entities. A network node 110 is a network node that communicates with UEs 120. As shown, a network node 110 may include one or more network nodes. For example, a network node 110 may be an aggregated network node, meaning that the aggregated network node is configured to utilize a radio protocol stack that is physically or logically integrated within a single radio access network (RAN) node (e.g., within a single device or unit). As another example, a network node 110 may be a disaggregated network node (sometimes referred to as a disaggregated base station), meaning that the network node 110 is configured to utilize a protocol stack that is physically or logically distributed among two or more nodes (such as one or more central units (CUs), one or more distributed units (DUs), or one or more radio units (RUS)).

In some examples, a network node 110 is or includes a network node that communicates with UEs 120 via a radio access link, such as an RU. In some examples, a network node 110 is or includes a network node that communicates with other network nodes 110 via a fronthaul link or a midhaul link, such as a DU. In some examples, a network node 110 is or includes a network node that communicates with other network nodes 110 via a midhaul link or a core network via a backhaul link, such as a CU. In some examples, a network node 110 (such as an aggregated network node 110 or a disaggregated network node 110) may include multiple network nodes, such as one or more RUs, one or more CUs, and/or one or more DUs. A network node 110 may include, for example, an NR base station, an LTE base station, a Node B, an eNB (e.g., in 4G), a gNB (e.g., in 5G), an access point, a transmission reception point (TRP), a DU, an RU, a CU, a mobility element of a network, a core network node, a network element, a network equipment, a RAN node, or a combination thereof. In some examples, the network nodes 110 may be interconnected to one another or to one or more other network nodes 110 in the wireless network 100 through various types of fronthaul, midhaul, and/or backhaul interfaces, such as a direct physical connection, an air interface, or a virtual network, using any suitable transport network.

In some examples, a network node 110 may provide communication coverage for a particular geographic area. In the Third Generation Partnership Project (3GPP), the term “cell” can refer to a coverage area of a network node 110 and/or a network node subsystem serving this coverage area, depending on the context in which the term is used. A network node 110 may provide communication coverage for a macro cell, a pico cell, a femto cell, and/or another type of cell. A macro cell may cover a relatively large geographic area (e.g., several kilometers in radius) and may allow unrestricted access by UEs 120 with service subscriptions. A pico cell may cover a relatively small geographic area and may allow unrestricted access by UEs 120 with service subscriptions. A femto cell may cover a relatively small geographic area (e.g., a home) and may allow restricted access by UEs 120 having association with the femto cell (e.g., UEs 120 in a closed subscriber group (CSG)). A network node 110 for a macro cell may be referred to as a macro network node. A network node 110 for a pico cell may be referred to as a pico network node. A network node 110 for a femto cell may be referred to as a femto network node or an in-home network node. In the example shown in FIG. 1, the network node 110a may be a macro network node for a macro cell 102a, the network node 110b may be a pico network node for a pico cell 102b, and the network node 110c may be a femto network node for a femto cell 102c. A network node may support one or multiple (e.g., three) cells. In some examples, a cell may not necessarily be stationary, and the geographic area of the cell may move according to the location of a network node 110 that is mobile (e.g., a mobile network node).

In some aspects, the terms “base station” or “network node” may refer to an aggregated base station, a disaggregated base station, an integrated access and backhaul (IAB) node, a relay node, or one or more components thereof. For example, in some aspects, “base station” or “network node” may refer to a CU, a DU, an RU, a Near-Real Time (Near-RT) RAN Intelligent Controller (RIC), or a Non-Real Time (Non-RT) RIC, or a combination thereof. In some aspects, the terms “base station” or “network node” may refer to one device configured to perform one or more functions, such as those described herein in connection with the network node 110. In some aspects, the terms “base station” or “network node” may refer to a plurality of devices configured to perform the one or more functions. For example, in some distributed systems, each of a quantity of different devices (which may be located in the same geographic location or in different geographic locations) may be configured to perform at least a portion of a function, or to duplicate performance of at least a portion of the function, and the terms “base station” or “network node” may refer to any one or more of those different devices. In some aspects, the terms “base station” or “network node” may refer to one or more virtual base stations or one or more virtual base station functions. For example, in some aspects, two or more base station functions may be instantiated on a single device. In some aspects, the terms “base station” or “network node” may refer to one of the base station functions and not another. In this way, a single device may include more than one base station.

The wireless network 100 may include one or more relay stations. A relay station is a network node that can receive a transmission of data from an upstream node (e.g., a network node 110 or a UE 120) and send a transmission of the data to a downstream node (e.g., a UE 120 or a network node 110). A relay station may be a UE 120 that can relay transmissions for other UEs 120. In the example shown in FIG. 1, the network node 110d (e.g., a relay network node) may communicate with the network node 110a (e.g., a macro network node) and the UE 120d in order to facilitate communication between the network node 110a and the UE 120d. A network node 110 that relays communications may be referred to as a relay station, a relay base station, a relay network node, a relay node, a relay, or the like.

The wireless network 100 may be a heterogeneous network that includes network nodes 110 of different types, such as macro network nodes, pico network nodes, femto network nodes, relay network nodes, or the like. These different types of network nodes 110 may have different transmit power levels, different coverage areas, and/or different impacts on interference in the wireless network 100. For example, macro network nodes may have a high transmit power level (e.g., 5 to 40 watts) whereas pico network nodes, femto network nodes, and relay network nodes may have lower transmit power levels (e.g., 0.1 to 2 watts).

A network controller 130 may couple to or communicate with a set of network nodes 110 and may provide coordination and control for these network nodes 110. The network controller 130 may communicate with the network nodes 110 via a backhaul communication link or a midhaul communication link. The network nodes 110 may communicate with one another directly or indirectly via a wireless or wireline backhaul communication link. In some aspects, the network controller 130 may be a CU or a core network device, or may include a CU or a core network device.

The UEs 120 may be dispersed throughout the wireless network 100, and each UE 120 may be stationary or mobile. A UE 120 may include, for example, an access terminal, a terminal, a mobile station, and/or a subscriber unit. A UE 120 may be a cellular phone (e.g., a smart phone), a personal digital assistant (PDA), a wireless modem, a wireless communication device, a handheld device, a laptop computer, a cordless phone, a wireless local loop (WLL) station, a tablet, a camera, a gaming device, a netbook, a smartbook, an ultrabook, a medical device, a biometric device, a wearable device (e.g., a smart watch, smart clothing, smart glasses, a smart wristband, smart jewelry (e.g., a smart ring or a smart bracelet)), an entertainment device (e.g., a music device, a video device, and/or a satellite radio), a vehicular component or sensor, a smart meter/sensor, industrial manufacturing equipment, a global positioning system device, a UE function of a network node, and/or any other suitable device that is configured to communicate via a wireless or wired medium.

Some UEs 120 may be considered machine-type communication (MTC) or evolved or enhanced machine-type communication (eMTC) UEs. An MTC UE and/or an eMTC UE may include, for example, a robot, a drone, a remote device, a sensor, a meter, a monitor, and/or a location tag, that may communicate with a network node, another device (e.g., a remote device), or some other entity. Some UEs 120 may be considered Internet-of-Things (IoT) devices, and/or may be implemented as NB-IoT (narrowband IoT) devices. Some UEs 120 may be considered a Customer Premises Equipment. A UE 120 may be included inside a housing that houses components of the UE 120, such as processor components and/or memory components. In some examples, the processor components and the memory components may be coupled together. For example, the processor components (e.g., one or more processors) and the memory components (e.g., a memory) may be operatively coupled, communicatively coupled, electronically coupled, and/or electrically coupled.

In general, any number of wireless networks 100 may be deployed in a given geographic area. Each wireless network 100 may support a particular RAT and may operate on one or more frequencies. A RAT may be referred to as a radio technology, an air interface, or the like. A frequency may be referred to as a carrier, a frequency channel, or the like. Each frequency may support a single RAT in a given geographic area in order to avoid interference between wireless networks of different RATs. In some cases, NR or 5G RAT networks may be deployed.

In some examples, two or more UEs 120 (e.g., shown as UE 120a and UE 120e) may communicate directly using one or more sidelink channels (e.g., without using a network node 110 as an intermediary to communicate with one another). For example, the UEs 120 may communicate using peer-to-peer (P2P) communications, device-to-device (D2D) communications, a vehicle-to-everything (V2X) protocol (e.g., which may include a vehicle-to-vehicle (V2V) protocol, a vehicle-to-infrastructure (V2I) protocol, or a vehicle-to-pedestrian (V2P) protocol), and/or a mesh network. In such examples, a UE 120 may perform scheduling operations, resource selection operations, and/or other operations described elsewhere herein as being performed by the network node 110.

Devices of the wireless network 100 may communicate using the electromagnetic spectrum, which may be subdivided by frequency or wavelength into various classes, bands, channels, or the like. For example, devices of the wireless network 100 may communicate using one or more operating bands. In 5G NR, two initial operating bands have been identified as frequency range designations FR1 (410 MHz-7.125 GHZ) and FR2 (24.25 GHz-52.6 GHz). It should be understood that although a portion of FR1 is greater than 6 GHZ, FR1 is often referred to (interchangeably) as a “Sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHZ-24.25 GHz). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR4a or FR4-1 (52.6 GHz-71 GHz), FR4 (52.6 GHz-114.25 GHZ), and FR5 (114.25 GHZ-300 GHz). Each of these higher frequency bands falls within the EHF band.

With the above examples in mind, unless specifically stated otherwise, it should be understood that the term “sub-6 GHz” or the like, if used herein, may broadly represent frequencies that may be less than 6 GHZ, may be within FR1, or may include mid-band frequencies. Further, unless specifically stated otherwise, it should be understood that the term “millimeter wave” or the like, if used herein, may broadly represent frequencies that may include mid-band frequencies, may be within FR2, FR4, FR4-a or FR4-1, and/or FR5, or may be within the EHF band. It is contemplated that the frequencies included in these operating bands (e.g., FR1, FR2, FR3, FR4, FR4-a, FR4-1, and/or FR5) may be modified, and techniques described herein are applicable to those modified frequency ranges.

In some aspects, a transmitting node (e.g., UE 120 or network node 110) may include a communication manager 140 or a communication manager 150. As described in more detail elsewhere herein, the communication manager 140 or the communication manager 150 may obtain a k-bit sequence of information bits; encode the k-bit sequence to an output sequence that corresponds to a length-n symbol sequence in a set of symbol sequences of length n and over an alphabet [symbol] ₘ in accordance with a first phase of energy-based arithmetic coding for PAS and a second phase of energy-based arithmetic coding for PAS, wherein: the first phase of energy-based arithmetic coding for PAS is associated with determining an energy E associated with the length-n symbol sequence; and the second phase of energy-based arithmetic coding for PAS is associated with determining the length-n symbol sequence based at least in part on multiple iterations, wherein each iteration is associated with deriving energies of subsequences of the length-n symbol sequence; and perform, to a receiving node, a transmission based at least in part on the length-n symbol sequence. Additionally, or alternatively, the communication manager 140 or the communication manager 150 may perform one or more other operations described herein.

As indicated above, FIG. 1 is provided as an example. Other examples may differ from what is described with regard to FIG. 1.

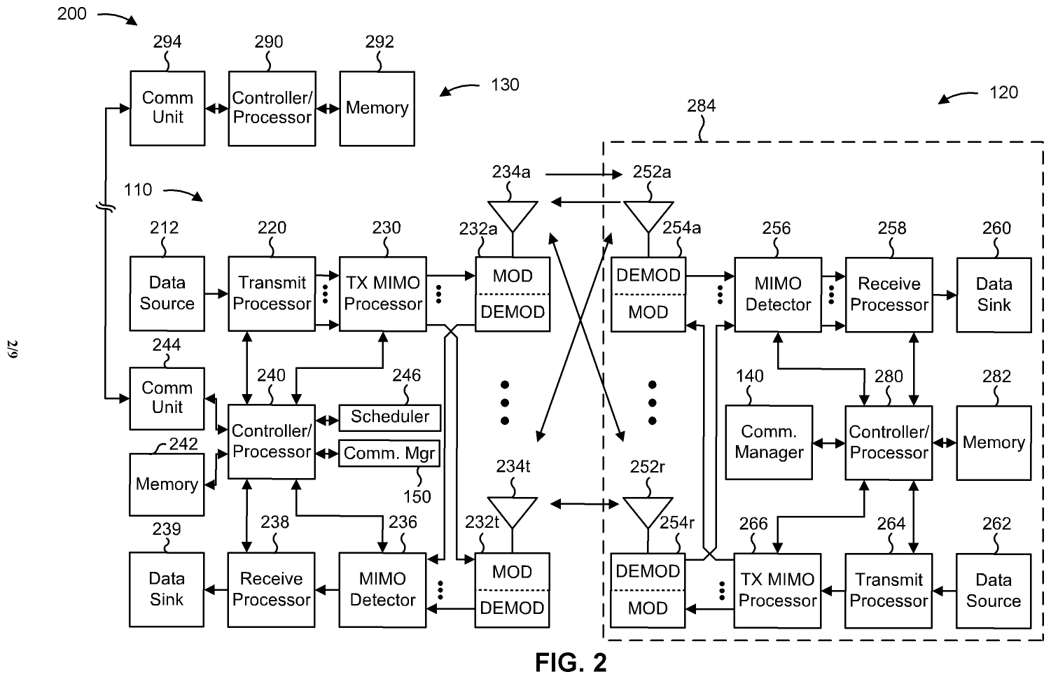

FIG. 2 is a diagram illustrating an example 200 of a network node 110 in communication with a UE 120 in a wireless network 100, in accordance with the present disclosure. The network node 110 may be equipped with a set of antennas 234a through 234t, such as T antennas (T≥1). The UE 120 may be equipped with a set of antennas 252a through 252r, such as R antennas (R≥1). The network node 110 of example 200 includes one or more radio frequency components, such as antennas 234 and a modem 254. In some examples, a network node 110 may include an interface, a communication component, or another component that facilitates communication with the UE 120 or another network node. Some network nodes 110 may not include radio frequency components that facilitate direct communication with the UE 120, such as one or more CUs, or one or more DUs.

At the network node 110, a transmit processor 220 may receive data, from a data source 212, intended for the UE 120 (or a set of UEs 120). The transmit processor 220 may select one or more modulation and coding schemes (MCSs) for the UE 120 based at least in part on one or more channel quality indicators (CQIs) received from that UE 120. The network node 110 may process (e.g., encode and modulate) the data for the UE 120 based at least in part on the MCS(s) selected for the UE 120 and may provide data symbols for the UE 120. The transmit processor 220 may process system information (e.g., for semi-static resource partitioning information (SRPI)) and control information (e.g., CQI requests, grants, and/or upper layer signaling) and provide overhead symbols and control symbols. The transmit processor 220 may generate reference symbols for reference signals (e.g., a cell-specific reference signal (CRS) or a demodulation reference signal (DMRS)) and synchronization signals (e.g., a primary synchronization signal (PSS) or a secondary synchronization signal (SSS)). A transmit (TX) multiple-input multiple-output (MIMO) processor 230 may perform spatial processing (e.g., precoding) on the data symbols, the control symbols, the overhead symbols, and/or the reference symbols, if applicable, and may provide a set of output symbol streams (e.g., T output symbol streams) to a corresponding set of modems 232 (e.g., T modems), shown as modems 232a through 232t. For example, each output symbol stream may be provided to a modulator component (shown as MOD) of a modem 232. Each modem 232 may use a respective modulator component to process a respective output symbol stream (e.g., for OFDM) to obtain an output sample stream. Each modem 232 may further use a respective modulator component to process (e.g., convert to analog, amplify, filter, and/or upconvert) the output sample stream to obtain a downlink signal. The modems 232a through 232t may transmit a set of downlink signals (e.g., T downlink signals) via a corresponding set of antennas 234 (e.g., T antennas), shown as antennas 234a through 234t.

At the UE 120, a set of antennas 252 (shown as antennas 252a through 252r) may receive the downlink signals from the network node 110 and/or other network nodes 110 and may provide a set of received signals (e.g., R received signals) to a set of modems 254 (e.g., R modems), shown as modems 254a through 254r. For example, each received signal may be provided to a demodulator component (shown as DEMOD) of a modem 254. Each modem 254 may use a respective demodulator component to condition (e.g., filter, amplify, downconvert, and/or digitize) a received signal to obtain input samples. Each modem 254 may use a demodulator component to further process the input samples (e.g., for OFDM) to obtain received symbols. A MIMO detector 256 may obtain received symbols from the modems 254, may perform MIMO detection on the received symbols if applicable, and may provide detected symbols. A receive processor 258 may process (e.g., demodulate and decode) the detected symbols, may provide decoded data for the UE 120 to a data sink 260, and may provide decoded control information and system information to a controller/processor 280. The term “controller/processor” may refer to one or more controllers, one or more processors, or a combination thereof. A channel processor may determine a reference signal received power (RSRP) parameter, a received signal strength indicator (RSSI) parameter, a reference signal received quality (RSRQ) parameter, and/or a CQI parameter, among other examples. In some examples, one or more components of the UE 120 may be included in a housing 284.

The network controller 130 may include a communication unit 294, a controller/processor 290, and a memory 292. The network controller 130 may include, for example, one or more devices in a core network. The network controller 130 may communicate with the network node 110 via the communication unit 294.

One or more antennas (e.g., antennas 234a through 234t and/or antennas 252a through 252r) may include, or may be included within, one or more antenna panels, one or more antenna groups, one or more sets of antenna elements, and/or one or more antenna arrays, among other examples. An antenna panel, an antenna group, a set of antenna elements, and/or an antenna array may include one or more antenna elements (within a single housing or multiple housings), a set of coplanar antenna elements, a set of non-coplanar antenna elements, and/or one or more antenna elements coupled to one or more transmission and/or reception components, such as one or more components of FIG. 2.

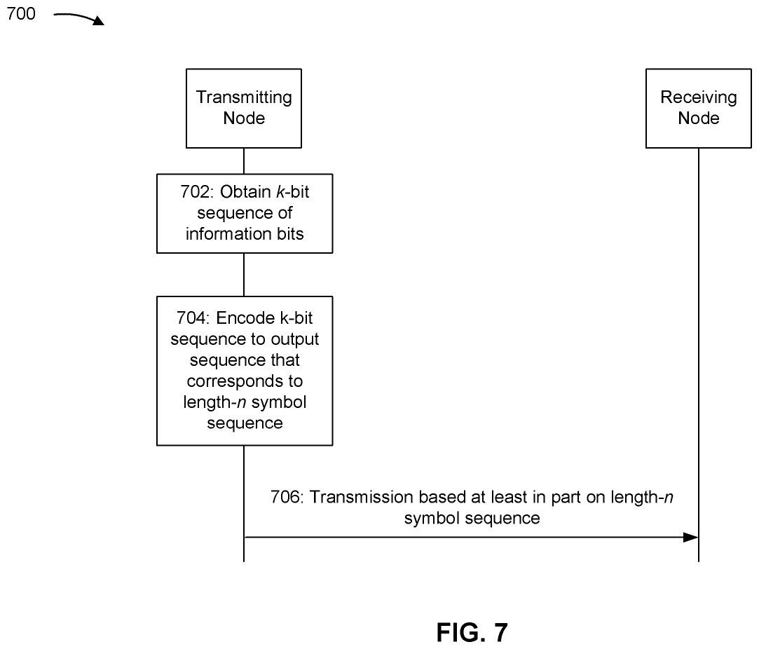

On the uplink, at the UE 120, a transmit processor 264 may receive and process data from a data source 262 and control information (e.g., for reports that include RSRP, RSSI, RSRQ, and/or CQI) from the controller/processor 280. The transmit processor 264 may generate reference symbols for one or more reference signals. The symbols from the transmit processor 264 may be precoded by a TX MIMO processor 266 if applicable, further processed by the modems 254 (e.g., for DFT-s-OFDM or CP-OFDM), and transmitted to the network node 110. In some examples, the modem 254 of the UE 120 may include a modulator and a demodulator. In some examples, the UE 120 includes a transceiver. The transceiver may include any combination of the antenna(s) 252, the modem(s) 254, the MIMO detector 256, the receive processor 258, the transmit processor 264, and/or the TX MIMO processor 266. The transceiver may be used by a processor (e.g., the controller/processor 280) and the memory 282 to perform aspects of any of the methods described herein (e.g., with reference to FIGS. 7-9).

At the network node 110, the uplink signals from UE 120 and/or other UEs may be received by the antennas 234, processed by the modem 232 (e.g., a demodulator component, shown as DEMOD, of the modem 232), detected by a MIMO detector 236 if applicable, and further processed by a receive processor 238 to obtain decoded data and control information sent by the UE 120. The receive processor 238 may provide the decoded data to a data sink 239 and provide the decoded control information to the controller/processor 240. The network node 110 may include a communication unit 244 and may communicate with the network controller 130 via the communication unit 244. The network node 110 may include a scheduler 246 to schedule one or more UEs 120 for downlink and/or uplink communications. In some examples, the modem 232 of the network node 110 may include a modulator and a demodulator. In some examples, the network node 110 includes a transceiver. The transceiver may include any combination of the antenna(s) 234, the modem(s) 232, the MIMO detector 236, the receive processor 238, the transmit processor 220, and/or the TX MIMO processor 230. The transceiver may be used by a processor (e.g., the controller/processor 240) and the memory 242 to perform aspects of any of the methods described herein (e.g., with reference to FIGS. 7-9).

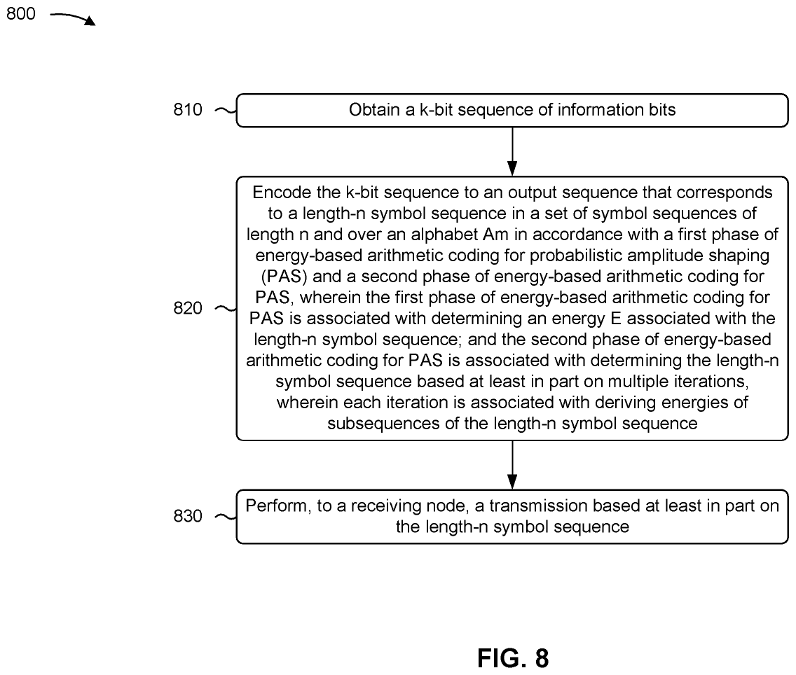

The controller/processor 240 of the network node 110, the controller/processor 280 of the UE 120, and/or any other component(s) of FIG. 2 may perform one or more techniques associated with energy-based arithmetic coding for PAS, as described in more detail elsewhere herein. In some aspects, the transmitting node described herein is the network node 110, is included in the network node 110, or includes one or more components of the network node 110 shown in FIG. 2. In some aspects, the transmitting node described herein is the UE 120, is included in the UE 120, or includes one or more components of the UE 120 shown in FIG. 2. For example, the controller/processor 240 of the network node 110, the controller/processor 280 of the UE 120, and/or any other component(s) of FIG. 2 may perform or direct operations of, for example, process 800 of FIG. 8, and/or other processes as described herein. The memory 242 and the memory 282 may store data and program codes for the network node 110 and the UE 120, respectively. In some examples, the memory 242 and/or the memory 282 may include a non-transitory computer-readable medium storing one or more instructions (e.g., code and/or program code) for wireless communication. For example, the one or more instructions, when executed (e.g., directly, or after compiling, converting, and/or interpreting) by one or more processors of the network node 110 and/or the UE 120, may cause the one or more processors, the UE 120, and/or the network node 110 to perform or direct operations of, for example, process 800 of FIG. 8, and/or other processes as described herein. In some examples, executing instructions may include running the instructions, converting the instructions, compiling the instructions, and/or interpreting the instructions, among other examples.

In some aspects, a transmitting node (e.g., UE 120 or network node 110) includes means for obtaining a k-bit sequence of information bits; means for encoding the k-bit sequence to an output sequence that corresponds to a length-n symbol sequence in a set of symbol sequences of length n and over an alphabet [symbol] ₘ in accordance with a first phase of energy-based arithmetic coding for PAS and a second phase of energy-based arithmetic coding for PAS, wherein: the first phase of energy-based arithmetic coding for PAS is associated with determining an energy E associated with the length-n symbol sequence; and the second phase of energy-based arithmetic coding for PAS is associated with determining the length-n symbol sequence based at least in part on multiple iterations, wherein each iteration is associated with deriving energies of subsequences of the length-n symbol sequence; and means for performing, to a receiving node, a transmission based at least in part on the length-n symbol sequence. The means for the transmitting node to perform operations described herein may include, for example, one or more of communication manager 140, antenna 252, modem 254, MIMO detector 256, receive processor 258, transmit processor 264, TX MIMO processor 266, controller/processor 280, or memory 282. The means for the transmitting node to perform operations described herein may include, for example, one or more of communication manager 150, transmit processor 220, TX MIMO processor 230, modem 232, antenna 234, MIMO detector 236, receive processor 238, controller/processor 240, memory 242, or scheduler 246.

While blocks in FIG. 2 are illustrated as distinct components, the functions described above with respect to the blocks may be implemented in a single hardware, software, or combination component or in various combinations of components. For example, the functions described with respect to the transmit processor 264, the receive processor 258, and/or the TX MIMO processor 266 may be performed by or under the control of the controller/processor 280.

As indicated above, FIG. 2 is provided as an example. Other examples may differ from what is described with regard to FIG. 2.

Deployment of communication systems, such as 5G NR systems, may be arranged in multiple manners with various components or constituent parts. In a 5G NR system, or network, a network node, a network entity, a mobility element of a network, a RAN node, a core network node, a network element, a base station, or a network equipment may be implemented in an aggregated or disaggregated architecture. For example, a base station (such as a Node B (NB), an evolved NB (eNB), an NR BS, a 5G NB, an access point (AP), a TRP, or a cell, among other examples), or one or more units (or one or more components) performing base station functionality, may be implemented as an aggregated base station (also known as a standalone base station or a monolithic base station) or a disaggregated base station. “Network entity” or “network node” may refer to a disaggregated base station, or to one or more units of a disaggregated base station (such as one or more CUs, one or more DUs, one or more RUs, or a combination thereof).

An aggregated base station (e.g., an aggregated network node) may be configured to utilize a radio protocol stack that is physically or logically integrated within a single RAN node (e.g., within a single device or unit). A disaggregated base station (e.g., a disaggregated network node) may be configured to utilize a protocol stack that is physically or logically distributed among two or more units (such as one or more CUs, one or more DUs, or one or more RUs). In some examples, a CU may be implemented within a network node, and one or more DUs may be co-located with the CU, or alternatively, may be geographically or virtually distributed throughout one or multiple other network nodes. The DUs may be implemented to communicate with one or more RUs. Each of the CU, DU, and RU also can be implemented as virtual units, such as a virtual central unit (VCU), a virtual distributed unit (VDU), or a virtual radio unit (VRU), among other examples.

Base station-type operation or network design may consider aggregation characteristics of base station functionality. For example, disaggregated base stations may be utilized in an IAB network, an open radio access network (O-RAN (such as the network configuration sponsored by the O-RAN Alliance)), or a virtualized radio access network (vRAN, also known as a cloud radio access network (C-RAN)) to facilitate scaling of communication systems by separating base station functionality into one or more units that can be individually deployed. A disaggregated base station may include functionality implemented across two or more units at various physical locations, as well as functionality implemented for at least one unit virtually, which can enable flexibility in network design. The various units of the disaggregated base station can be configured for wired or wireless communication with at least one other unit of the disaggregated base station.

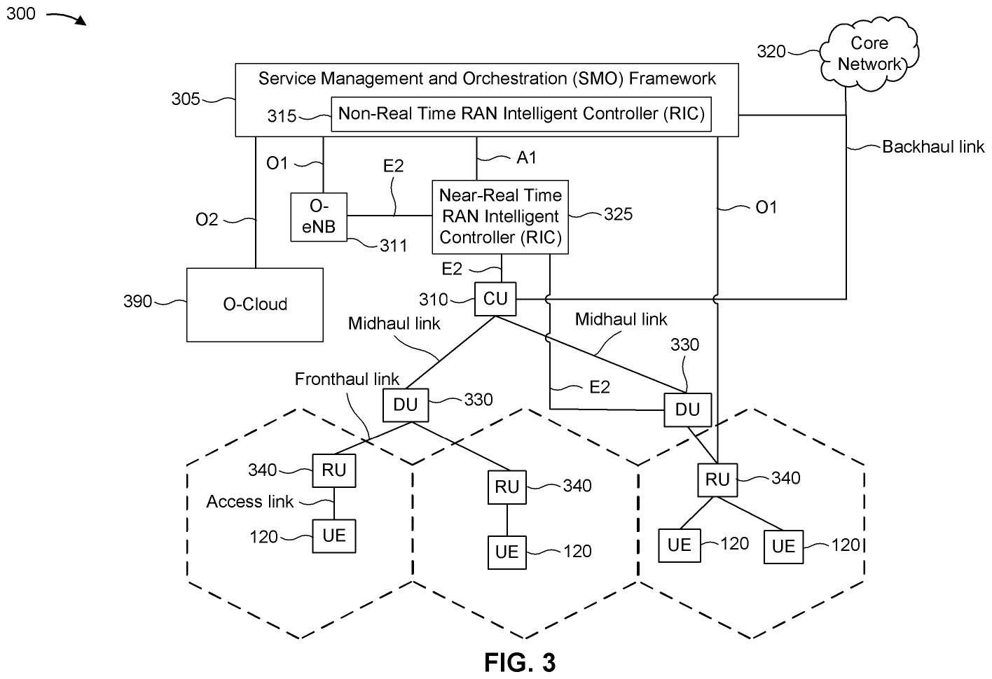

FIG. 3 is a diagram illustrating an example disaggregated base station architecture 300, in accordance with the present disclosure. The disaggregated base station architecture 300 may include a CU 310 that can communicate directly with a core network 320 via a backhaul link, or indirectly with the core network 320 through one or more disaggregated control units (such as a Near-RT RIC 325 via an E2 link, or a Non-RT RIC 315 associated with a Service Management and Orchestration (SMO) Framework 305, or both). A CU 310 may communicate with one or more DUs 330 via respective midhaul links, such as through F1 interfaces. Each of the DUs 330 may communicate with one or more RUs 340 via respective fronthaul links. Each of the RUs 340 may communicate with one or more UEs 120 via respective radio frequency (RF) access links. In some implementations, a UE 120 may be simultaneously served by multiple RUs 340.

Each of the units, including the CUS 310, the DUs 330, the RUs 340, as well as the Near-RT RICs 325, the Non-RT RICs 315, and the SMO Framework 305, may include one or more interfaces or be coupled with one or more interfaces configured to receive or transmit signals, data, or information (collectively, signals) via a wired or wireless transmission medium. Each of the units, or an associated processor or controller providing instructions to one or multiple communication interfaces of the respective unit, can be configured to communicate with one or more of the other units via the transmission medium. In some examples, each of the units can include a wired interface, configured to receive or transmit signals over a wired transmission medium to one or more of the other units, and a wireless interface, which may include a receiver, a transmitter or transceiver (such as an RF transceiver), configured to receive or transmit signals, or both, over a wireless transmission medium to one or more of the other units.

In some aspects, the CU 310 may host one or more higher layer control functions. Such control functions can include radio resource control (RRC) functions, packet data convergence protocol (PDCP) functions, or service data adaptation protocol (SDAP) functions, among other examples. Each control function can be implemented with an interface configured to communicate signals with other control functions hosted by the CU 310. The CU 310 may be configured to handle user plane functionality (for example, Central Unit-User Plane (CU-UP) functionality), control plane functionality (for example, Central Unit-Control Plane (CU-CP) functionality), or a combination thereof. In some implementations, the CU 310 can be logically split into one or more CU-UP units and one or more CU-CP units. A CU-UP unit can communicate bidirectionally with a CU-CP unit via an interface, such as the E1 interface when implemented in an O-RAN configuration. The CU 310 can be implemented to communicate with a DU 330, as necessary, for network control and signaling.

Each DU 330 may correspond to a logical unit that includes one or more base station functions to control the operation of one or more RUs 340. In some aspects, the DU 330 may host one or more of a radio link control (RLC) layer, a MAC layer, and one or more high physical (PHY) layers depending, at least in part, on a functional split, such as a functional split defined by the 3GPP. In some aspects, the one or more high PHY layers may be implemented by one or more modules for forward error correction (FEC) encoding and decoding, scrambling, and modulation and demodulation, among other examples. In some aspects, the DU 330 may further host one or more low PHY layers, such as implemented by one or more modules for a fast Fourier transform (FFT), an inverse FFT (iFFT), digital beamforming, or physical random access channel (PRACH) extraction and filtering, among other examples. Each layer (which also may be referred to as a module) can be implemented with an interface configured to communicate signals with other layers (and modules) hosted by the DU 330, or with the control functions hosted by the CU 310.

Each RU 340 may implement lower-layer functionality. In some deployments, an RU 340, controlled by a DU 330, may correspond to a logical node that hosts RF processing functions or low-PHY layer functions, such as performing an FFT, performing an iFFT, digital beamforming, or PRACH extraction and filtering, among other examples, based on a functional split (for example, a functional split defined by the 3GPP), such as a lower layer functional split. In such an architecture, each RU 340 can be operated to handle over the air (OTA) communication with one or more UEs 120. In some implementations, real-time and non-real-time aspects of control and user plane communication with the RU(s) 340 can be controlled by the corresponding DU 330. In some scenarios, this configuration can enable each DU 330 and the CU 310 to be implemented in a cloud-based RAN architecture, such as a vRAN architecture.

The SMO Framework 305 may be configured to support RAN deployment and provisioning of non-virtualized and virtualized network elements. For non-virtualized network elements, the SMO Framework 305 may be configured to support the deployment of dedicated physical resources for RAN coverage requirements, which may be managed via an operations and maintenance interface (such as an O1 interface). For virtualized network elements, the SMO Framework 305 may be configured to interact with a cloud computing platform (such as an open cloud (O-Cloud) platform 390) to perform network element life cycle management (such as to instantiate virtualized network elements) via a cloud computing platform interface (such as an O2 interface). Such virtualized network elements can include, but are not limited to, CUs 310, DUs 330, RUs 340, non-RT RICs 315, and Near-RT RICs 325. In some implementations, the SMO Framework 305 can communicate with a hardware aspect of a 4G RAN, such as an open eNB (O-eNB) 311, via an O1 interface. Additionally, in some implementations, the SMO Framework 305 can communicate directly with each of one or more RUs 340 via a respective O1 interface. The SMO Framework 305 also may include a Non-RT RIC 315 configured to support functionality of the SMO Framework 305.

The Non-RT RIC 315 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 325. The Non-RT RIC 315 may be coupled to or communicate with (such as via an A1 interface) the Near-RT RIC 325. The Near-RT RIC 325 may be configured to include a logical function that enables near-real-time control and optimization of RAN elements and resources via data collection and actions over an interface (such as via an E2 interface) connecting one or more CUs 310, one or more DUs 330, or both, as well as an O-eNB, with the Near-RT RIC 325.

In some implementations, to generate AI/ML models to be deployed in the Near-RT RIC 325, the Non-RT RIC 315 may receive parameters or external enrichment information from external servers. Such information may be utilized by the Near-RT RIC 325 and may be received at the SMO Framework 305 or the Non-RT RIC 315 from non-network data sources or from network functions. In some examples, the Non-RT RIC 315 or the Near-RT RIC 325 may be configured to tune RAN behavior or performance. For example, the Non-RT RIC 315 may monitor long-term trends and patterns for performance and employ AI/ML models to perform corrective actions through the SMO Framework 305 (such as reconfiguration via an O1 interface) or via creation of RAN management policies (such as A1 interface policies).

As indicated above, FIG. 3 is provided as an example. Other examples may differ from what is described with regard to FIG. 3.

In a wireless network, a transmitting node may encode information according to a certain forward-error-correction (FEC) coding scheme to improve transmission reliability. The transmitting node may then modulate the encoded information according to a certain modulation scheme for transmission. A modulation scheme may have a certain constellation with certain constellation points, which may also be referred to as modulation symbols. A transmission using a modulation scheme may carry information represented by modulation symbols from a certain set of constellation points defined for the modulation scheme.

Traditional signal constellations, such as amplitude shift keying (ASK) and quadrature amplitude modulation (QAM), are characterized by constellation points with equal distance and each constellation point is transmitted with the same probability. Unfortunately, such constellations result in a gap to the Shannon limit. To close this gap and to increase the spectral efficiency, constellation shaping may be applied. For an additive white Gaussian noise (AWGN) channel, constellation shaping may offer gains (termed shaping gain) up to 1.53 decibel (dB) in signal-to-noise ratio (SNR) by utilizing Gaussian shaped constellations.

A favorable performance with data rate close to the channel capacity may be achieved by a constellation with a Gaussian-like distribution. Geometric constellation shaping (GCS) and probabilistic amplitude shaping (PAS) are particular examples to provide non-uniform distribution of constellation using QAM. For GCS, each constellation point may be used with equal probability, while the location of the constellation points has an unequal distance and is arranged to mimic the capacity-achieving distribution. For PAS, or more generally, probabilistic constellation shaping (PCS), a constellation may be used, e.g., ASK or QAM, with constellation points having equal distance, and different probabilities may be assigned to different constellation points.

Distribution matching (DM) may be applied to a sequence of k uniformly distributed bits into a sequence of n symbols with a target or desired probability distribution. Here, the symbols may be from an alphabet. When a DM is used for constellation shaping, e.g., for PAS, the symbol alphabet may be related to the modulation scheme. For instance, for 16-QAM, the symbol alphabet may be {1, 3}, and for 64-QAM, the symbol alphabet may be {1, 3, 5, 7}. A composition may be an ordered tuple, counting the occurrences of each symbol in a symbol alphabet. For example, for the 16-QAM case, if the symbol sequences are of length 10, then (2, 8) may be an example of a composition, with 2 occurrences of 1s and 8 occurrences of 3s. Constant composition distribution matching (CCDM) is a particular example of a DM. A particular characteristic of CCDM may be that all output symbol sequences have the same (e.g., identical) composition.

Fixed-to-fixed DM schemes may be used at transmitting nodes prior to encoding and at receiving nodes prior to decoding. A transmitting node may include an amplitude shaper, which may use fixed-to-fixed DM, and a receiving node may include an amplitude deshaper, which may use fixed-to-fixed distribution dematching. Fixed-to-fixed DM schemes may provide various benefits for wireless communication systems. Fixed-to-fixed DM schemes may be associated with fewer variations on data segmentation at a transmitting node, and fewer processing tasks to handle at a receiving node, both of which may result in increased energy efficiency at the transmitting node and/or the receiving node.

In wireless communication systems, higher-order modulation (e.g., 16-QAM, 64-QAM, or 256-QAM) may be used. Constellations in these systems may be fixed and each constellation point may be used with an equal probability. The channel capacity over the AWGN channel may be achievable when an input distribution is a Gaussian distribution. A difference between the SNR to achieve a rate with a given MCS and the SNR at which an optimal capacity-achieving scheme could operate at the same rate may be referred to as a shaping gap. For the AWGN channel, the shaping gap may be asymptotically equal to about 1.53 dB when channel inputs are uniformly distributed. Existing techniques to reduce or close the shaping gap may include geometric shaping and probabilistic shaping. Geometric shaping may implement equiprobable signaling with Gaussian-like distributed constellation points. Probabilistic shaping may employ equidistant constellation points and implement a non-uniform (e.g., Gaussian-like) signal distribution.

Traditional approaches to probabilistic shaping may include trellis shaping and shell mapping. PAS may be another technique to perform probabilistic shaping. PAS may combine an outer layer of shaping with an inner layer of binary FEC to provide a low-complexity and flexible integration with existing bit-interleaved coded modulation (BICM) schemes. PAS may provide a relatively large shaping gain and inherent rate adaptation functionality.

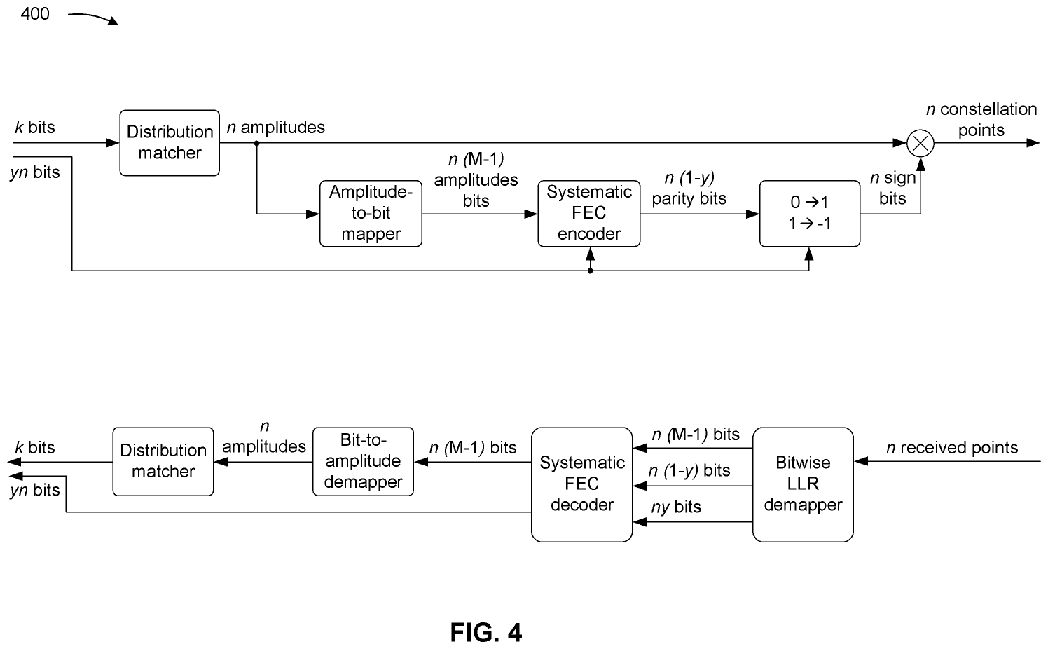

FIG. 4 is a diagram illustrating an example 400 of a PAS architecture, in accordance with the present disclosure.

As shown by reference number 402, in a transmitter chain of a PAS architecture, k bits may be provided to a distribution matcher, where k is the length of input information bits. The distribution matcher may output n amplitudes, which may be based at least in part on the k bits. The n amplitudes may be provided to an amplitude-to-bit mapper. The amplitude-to-bit mapper may output n(M−1) amplitude bits, which may be based at least in part on the n amplitudes, and where M indicates a modulation order. The n(M−1) amplitude bits may be provided to a systematic FEC encoder. The systematic FEC encoder may output n(1−γ) parity bits, which may be based at least in part on the n(M−1) amplitude bits, and where γ indicates an additional fraction of information bits. The (1−γ) parity bits may be converted to n sign bits, where the n sign bits may be based at least in part on the (1−γ) parity bits and γn information bits. When converting the (1−γ) parity bits to the n sign bits, a “O” may be mapped to “1” and a “1” may be mapped to “−1”. Further, n constellation points may be formed based at least in part on the n sign bits.

As shown by reference number 404, n received points may be provided to a bitwise LLR demapper. The bitwise LLR demapper may output n(M−1) amplitude bits, n(1−γ) parity bits, and nγ bits, which may be based at least in part on the n received points. The nγ bits may refer to an additional number of information bits, and these additional information bits may be used for rate adaptation. The n(M−1) amplitude bits, the n(1−γ) parity bits, and the nγ bits may be provided to a systematic FEC decoder. The systematic FEC decoder may output the n(M−1). The systematic FEC decoder may output yn information bits, which may be based at least in part on the n(M−1) amplitude bits, the n(1−γ) parity bits, and/or the nγ bits. The systematic FEC decoder may provide the n(M−1) amplitude bits to a bit-to-amplitude demapper. The bit-to-amplitude demapper may output n amplitudes, which may be based at least in part on the n(M−1) amplitude bits. The bit-to-amplitude demapper may provide the n amplitudes to a distribution dematcher. The distribution dematcher may determine k bits, which may be based at least in part on the n amplitudes.

As indicated above, FIG. 4 is provided as an example. Other examples may differ from what is described with regard to FIG. 4.

In PAS, a 2^{M}-ary ASK constellation {±1, ±3, . . . , ±(2^{N}−1)} with amplitude alphabet [symbol] ={1, 3, . . . , 2^{M}−1} may be defined. A DM rate (Ram) may be defined in accordance with:

$${R}_{dm} = \frac{k}{n} . \qquad ( 1 )$$

A systematic FEC code rate (R_{c}) may be defined in accordance with:

$${R}_{c} = \frac{M - 1 + γ}{M} . \qquad ( 2 )$$

The n(M−1) amplitude bits and the γn information bits may together constitute n(M−1+γ) bits as an input to the systematic FEC encoder, which may then generate the n(1−γ) parity bits. The n(1−γ) parity bits together with the γn information bits may be converted to the n sign bits, and may be pointwise multiplied with the n amplitudes from the output of the distribution matcher. A transmission rate (Rₜ) may be defined in accordance with: Rₜ=R_{dm}+γ.

A fixed-to-fixed DM may map a length-k bit sequence to a length-n amplitude sequence, and may induce a non-uniform distribution over amplitude symbols {1, 3, . . . , 2^{M}−1}. The k bits may be assumed to be independent and identically distributed with a uniform distribution. The non-uniform distribution over the amplitude symbols induced by DM may be closer to a capacity-achieving distribution than the uniform distribution (e.g., being more Gaussian-like or being a Maxwell-Boltzmann distribution in the AWGN setting).

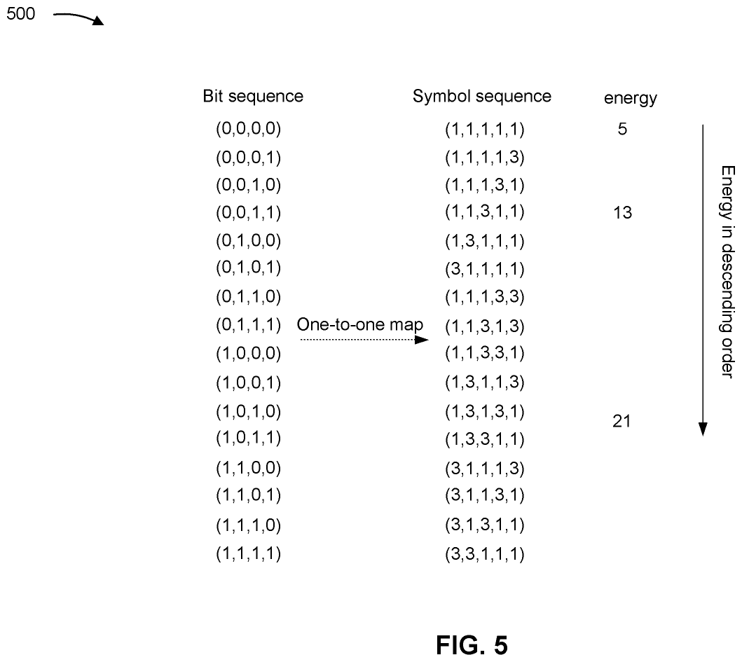

FIG. 5 is a diagram illustrating an example 500 of sphere shaping, in accordance with the present disclosure.

As shown in FIG. 5, sphere shaping may consider 2^{k} symbol sequences of length n with minimal energy. A mapping from length-k bit sequences (e.g., (0, 0, 0, 0), (0, 0, 0, 1), and so on) to length-n symbol (e.g., amplitude) sequences (e.g., (1, 1, 1, 1, 1), (1, 1, 1, 1, 3), and so on) may be a one-to-one mapping. Sphere shaping may use minimum energy sequences, such that a resulting marginal distribution may be close to a Maxwell-Boltzmann distribution. With sphere shaping, a sequence energy may be below a defined threshold. Sphere shaping may provide a near optimal shaping gain and a minimum energy use for a given rate. However, traditional sphere shaping algorithms have high computational or storage complexity.

As indicated above, FIG. 5 is provided as an example. Other examples may differ from what is described with regard to FIG. 5.

For an alphabet [symbol] ₘ, m>1 may be an integer and [symbol] ₘ={a₁, a₂, . . . , aₘ} may be a symbol alphabet of size m. An ordering that is less than an ordering on the alphabet [symbol] ₘ may be imposed, such that aᵢ<aᵢ₊₁ for each i, i.e., a₁<a₂< . . . <aₘ. With respect to an energy of a symbol, given an alphabet [symbol] ₘ={a₁, a₂, . . . , aₘ} of size m, the energy of symbol aᵢ for each i may be denoted by E(aᵢ). Symbol energies may be distinct, and for any i∈{1, 2, . . . , m−1}, an assumption may be made that 0≤E(aᵢ)<E(aᵢ₊₁), and where “E” indicates a set membership.

For ASK constellations, [symbol] ₘ={1, 3, . . . , 2^{M}−1} so that m=2^{M}−1, and {−1, 1}× [symbol] ₘ may correspond to a 2^{M}-ary ASK alphabet (e.g., m depends on a modulation order). In this case, aᵢ=2i−1 so that a₁=1, a₂=3, . . . , aₘ=2^{M}−1. In a first example of symbol energy, for each i, E(aᵢ)=(2i−1)². In a second example of symbol energy, for each i, E(aᵢ)=[i(i−1)]/2. Further, since 8E(aᵢ)+1=(2i−1)², E(aᵢ) may only involve a rescaling of (2i−1)².

With respect to an energy of a sequence, given an alphabet Aₘ of size m, a sequence s=(s₁, s₂, . . . , sₙ) may be defined, where each element of the sequence may take values in the alphabet [symbol] ₘ. The energy of the sequence s, denoted by E(s), may be defined as an accumulation (e.g., a summation) of a plurality of symbol energies (e.g., all symbol energies) in accordance with:

$$E ( s ) = {\sum }_{l = 1}^{n} E ( {s}_{l} ) . \qquad ( 3 )$$

The sequence s may be over alphabet [symbol] ₘ and may have a length of n, where “over alphabet [symbol] ₘ” may indicate that each element (e.g., symbol) of the sequence belongs to alphabet [symbol] ₘ. A total quantity of sequences over [symbol] ₘ having length n and energy E may be denoted by N^{[m]}(n, E). When {s=(s₁, s₂, . . . , sₙ)|sᵢ∈ [symbol] ₘ, ∀i, E(s)=E} denotes the set of all sequences over alphabet [symbol] ₘ and having length n and energy E, then N^{[m]}(n, E) may be the cardinality of this set. When an underlying size m is clear from the context, N(n, E) may be written as a proxy, where N(n, E) may depend on m, n and E, and where N(n, E) may indicate the total quantity of sequences over [symbol] ₘ having length n and energy E. Further, N(n, E) may be referred to as a sequence quantity.

Further, [symbol] ₘ={a₁, a₂, . . . , aₘ} may be an alphabet of size m, and symbol aᵢ may have energy E(aᵢ), and

$${N}_{c}^{[ m ]} ( n , E )$$

may denote the number of symbol sequences over [symbol] ₘ, with each sequence having length n and energy at most E. A set of all sequences over alphabet [symbol] ₘ having length n and energy at most E may be denoted by {s=(s₁, s₂, . . . , sₙ)|sᵢ∈ [symbol] ₘ, ∀i, E(s)≤E}. Then,

$${N}_{c}^{[ m ]} ( n , E ) = \vert \{ s = ( {s}_{1} , {s}_{2} , … , {s}_{n} ) \vert {s}_{i} ∈ {m}_{} , ∀ i , E ( s ) \leq E \} \vert . \qquad ( 4 )$$

When an underlying size m is clear from the context, N_{c}(n, E) may be written as a proxy. Further, N(n, E) may be referred to as a cumulative sequence quantity.

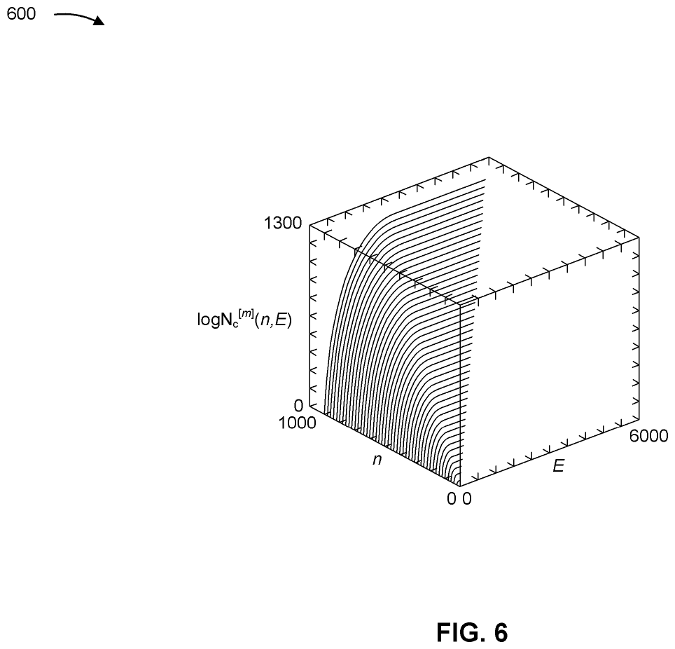

FIG. 6 is a diagram illustrating an example 600 of symbol sequences over an alphabet, in accordance with the present disclosure.

As shown in FIG. 6, a number of symbol sequences over [symbol] ₘ, with each sequence having length n and energy at most E, which may be denoted by

$${N}_{c}^{[ m ]} ( n , E )$$

or N_{c}(n, E), may be defined. In this example, m=4 and the alphabet [symbol] ₄ may be such that E(a₁)=0, E(a₂)=1, E(a₃)=3 and E(a₄)=6. Further, values for log

$${N}_{c}^{[ m ]} ( n , E )$$

are shown for various values of n and E. When m is fixed, log

$${N}_{c}^{[ m ]} ( n , E )$$

may be viewed as a two-variable function of n and E.

As indicated above, FIG. 6 is provided as an example. Other examples may differ from what is described with regard to FIG. 6.

A traditional fixed-to-fixed DM scheme may be a constant composition DM (CCDM), which may suffer from a relatively large rate loss at small-to-medium sequence lengths. Another traditional scheme is multiset partition DM (MPDM), which may have a smaller rate loss yet needs to predetermine a relatively large amount of information for composition selection, which may result in a relatively large computation and/or storage complexity.

In various aspects of techniques and apparatuses described herein, a transmitting node (e.g., a UE or a network node) may obtain a k-bit sequence of information bits. The UE may encode the k-bit sequence to a length-n symbol sequence (an output sequence) in a set of symbol sequences ( [symbol] (m, n, Ē)) of length n and over an alphabet [symbol] ₘ in accordance with a first phase of energy-based arithmetic coding for PAS and a second phase of energy-based arithmetic coding for PAS. The first phase of energy-based arithmetic coding for PAS may be associated with determining an energy E associated with the length-n symbol sequence. The second phase of energy-based arithmetic coding for PAS may be associated with determining the length-n symbol sequence based at least in part on multiple iterations. Each iteration may be associated with deriving energies of subsequences of the length-n symbol sequence. The transmitting node may perform, to a receiving node (e.g., a network node or a UE), a transmission based at least in part on the length-n symbol sequence. The transmitting node may derive the length-n symbol sequence from the k-bit sequence using a hierarchical energy-based arithmetic coding for PAS, which may improve an energy efficiency of the transmitting node. As compared to traditional schemes, energy-based arithmetic coding for PAS may provide a larger (e.g., nearly-optimal) shaping gain, while also being capable of performing its shaping operation in an efficient manner (e.g., with low computation and storage complexity).

FIG. 7 is a diagram illustrating an example 700 associated with energy-based arithmetic coding for PAS. As shown in FIG. 7, example 700 includes communication between a transmitting node (e.g., UE 120 or network node 110) and a receiving node (e.g., UE 120 or network node 110). In some aspects, the transmitting node and the receiving node may be included in a wireless network, such as wireless network 100.

As shown by reference number 702, the transmitting node (e.g., a UE or a network node) may obtain a k-bit sequence of information bits. The transmitting node may obtain the k-bit sequence of information bits at a distribution matcher, which may be part of a transmitter chain associated with the transmitting node.

As shown by reference number 704, the transmitting node may encode the k-bit sequence to a length-n symbol sequence (an output sequence) in a set of symbol sequences ( [symbol] (m, n, Ē)) of length n and over an alphabet [symbol] ₘ in accordance with a first phase of hierarchical energy-based arithmetic coding for PAS and a second phase of hierarchical energy-based arithmetic coding for PAS. In other words, the transmitting node may determine, based at least in part on the k-bit sequence, the length-n symbol sequence. The length-n symbol sequence may correspond to the output sequence. The first phase may be associated with determining an energy E associated with the length-n symbol sequence. The second phase may be associated with determining the length-n symbol sequence based at least in part on multiple iterations, where each iteration may be associated with deriving an energy of a subsequence of the length-n symbol sequence.

In some aspects, the transmitting node may perform a hierarchical energy-based arithmetic coding for PAS. For a symbol alphabet [symbol] ₘ={a₁, a₂, . . . , aₘ} of size m, where aᵢ has energy E(aᵢ), the set of all symbol sequences of length n and over [symbol] ₘ may be denoted by [symbol] (m, n, Ē), where each sequence

$${s}_{1}^{n}$$

in the set [symbol] (m, n, Ē) has energy at most equal to Ē. In other words, for any

$${s}_{1}^{n}$$

∈ [symbol] (m, n, Ē), E(s₁ⁿ)≤Ē (e.g., for any sequence in that set, the sequence energy is less than or equal to E). A cardinality of the set [symbol] (m, n, Ē) (e.g., the number of sequences in [symbol] (m, n, Ē)) may be given by:

$$\vert 𝒮 ( m , n , \overline{E} ) \vert = {N}_{c}^{[ m ]} ( n , \overline{E} ) .$$

When the underlying size m is clear from the context N_{c}(n, Ē) may be written as a proxy for

$${N}_{c}^{[ m ]} ( n , \overline{E} ) .$$

In the sequence, n may be assumed to be a power of 2 (e.g., n=2^{R} for a positive integer R).

In some aspects, a sequence energy (Ē) may depend on [symbol] ₘ and n. For example, when a minimum symbol energy and a maximum symbol energy are assumed to be E(a₁) and E(aₘ), respectively, then a minimum energy and a maximum energy of a length-n symbol sequence over [symbol] ₘ may be equal to nE(a₁) and nE(aₘ), respectively, which may give a smallest and a largest meaningful Ē, respectively. A particular form of Ē may be represented by αn, where α may be between E(a₁) and E(aₘ) and n is the sequence length. For example, α may be taken as an average symbol energy, such that

$$α = {\sum }_{i = 1}^{m} E ( {a}_{i} ) / m .$$

As another example, α may be taken as a function of e^{-v}, where v is a parameter of a Maxwell-Boltzmann distribution. A specific choice of Ē may be irrelevant for the hierarchical energy-based arithmetic coding for PAS.

In some aspects, the transmitting node may use the hierarchical energy-based arithmetic coding for PAS. By using hierarchical energy-based arithmetic coding for PAS, the transmitting node may use an efficient scheme to encode (e.g., map) the length-k bit sequence into the length-n symbol sequence in [symbol] (m, n, Ē) (the set of all symbol sequences of length n and over [symbol] ₘ, and each sequence of which has energy at most equal to Ē) and to guarantee a unique decodability. In the hierarchical energy-based arithmetic coding for PAS, for an input, k may be the largest integer, such that:

$${2}^{- k} \geq \frac{1}{{N}_{c}^{[ m ]} ( n , \overline{E} )} . \qquad ( 5 )$$

A k-bit sequence (u₁, u₂, . . . , uₖ) that includes information bits may be interpreted as the dyadic number x∈[0, 1) with the binary expansion 0.u₁u₂ . . . uₖ, in accordance with:

$$x = {\sum }_{i = 1}^{k} {u}_{i} {2}^{- i} , \qquad ( 6 )$$

such that x may be between 0 and 1. Further, the dyadic number x, alphabet [symbol] ₘ, sequence length n, and maximum energy Ē may be available for hierarchical energy-based arithmetic coding for PAS. In some aspects, as an output, the transmitting node may use the hierarchical energy-based arithmetic coding for PAS to map the sequence (u₁, u₂, . . . , uₖ) to the length-n symbol sequence s=(s₁, s₂, . . . , sₙ) in [symbol] (m, n, Ē) based at least in part on the first phase and the second phase.

In some aspects, the first phase may involve an energy selection. During the first phase, the transmitting node may determine a number E between 0 and Ē, where the number E may specify the energy of the output sequence. The transmitting node may first determine the energy of the output sequence rather than the output sequence itself. The transmitting node may select the number E according to:

$$x ∈ [ \frac{{N}_{c} ( n , E - 1 )}{{N}_{c} ( n , \overline{E} )} , \frac{{N}_{c} ( n , E )}{{N}_{c} ( n , \overline{E} )} ) , \qquad ( 7 )$$

where x is a dyadic number. The transmitting node may determine the energy E associated with the length-n symbol sequence between zero and a maximum energy Ē, where the energy E is based at least in part on the dyadic number x interpreted from the k-bit sequence, the number of symbol sequences over an alphabet [symbol] ₘ (N_{c}), the sequence length n, and the maximum energy Ē. Then, during the first phase, the transmitting node may scale the dyadic number x to obtain a scaled dyadic number x′ according to:

$${x}^{′} = \frac{{N}_{c} ( n , \overline{E} ) x - {N}_{c} ( n , E - 1 )}{N ( n , E )} , \qquad ( 8 )$$

The transmitting node may scale the dyadic number x, to obtain the scaled dyadic number x′, based at least in part on the dyadic number x, the number of symbol sequences over [symbol] ₘ (N_{c}), the sequence length n, the energy E, and the maximum energy Ē. In some aspects, the transmitting node may determine the number E based at least in part on a bisection technique, since N_{c} is increasing in its second argument. During the first phase, the transmitting node may effectively partition the set [symbol] (m, n, Ē) into subsets, with each subset including sequences (e.g., all sequences) that have an equal energy.

In some aspects, a subinterval between N_{c}(n, E−1) and N_{c}(n, E) may correspond to all sequences in [symbol] (m, n, Ē) that has energy equal to E, and where a corresponding length is proportional to N_{c}(n, E)−N_{c}(n, E−1)=N(n, E). The subinterval may be an interval that starts after 0, and ends before 1.

In some aspects, during the first phase, the transmitting node may determine a plurality of N_{c} cumulative sequence quantities, where each N_{c} cumulative sequence quantity of the plurality of N_{c} cumulative sequence quantities may represent a total number of symbol sequences over the alphabet [symbol] ₘ, having the sequence length n, and having an energy below or equal to a respective energy level. Each cumulative sequence quantity may represent a total number associated with a respective set of symbol sequences. For example,

$${N}_{c}^{[ m ]} ( n , E ) , or {N}_{c}^{[ m ]} ( n , E - 1 ) , or {N}_{c}^{[ m ]} ( n , E + 1 )$$

are three such quantities, and correspond to three sets. For example,

$${N}_{c}^{[ m ]} ( n , E - 1 )$$

is the total number of symbol sequences over alphabet [symbol] ₘ, having the sequence length n, and having an energy below or equal to E−1.

In some aspects, during the first phase, the transmitting node may process the plurality of N_{c} cumulative sequence quantities, which may involve partitioning an interval into a plurality of (disjoint) subintervals based at least in part on the plurality of N_{c} cumulative sequence quantities. Each subinterval of the plurality of subintervals may correspond to a respective energy level. Each subinterval of the plurality of subintervals may have a length proportional to a respective N sequence quantity, and the respective N sequence quantity may represent a total number of symbol sequences over the alphabet [symbol] ₘ, having the sequence length n and having an energy exactly equal to the respective energy level.

In some aspects, during the first phase, the transmitting node may select an energy level based at least in part on the plurality of information bits and the plurality of subintervals. For example, the selection may be in accordance with Equation (7). The output sequence that is determined at the end of the second phase may have an energy equal to the energy level selected during the first phase.

In some aspects, in the second phase, when n is a power of 2, the following may be defined:

$${N}^{[ m ]} ( n , E ) = {\sum }_{{E}^{′} = 0}^{E} {N}^{[ m ]} ( \frac{n}{2} , {E}^{′} ) {N}^{[ m ]} ( \frac{n}{2} , E - {E}^{′} ) , \qquad ( 9 )$$

where N^{[m]}(n, E) is the total number of symbol sequences over [symbol] ₘ having length n and energy E, and E′ indicates an energy of a first-half subsequence of the output sequence, and E−E′ corresponds to an energy of a second-half subsequence of the output sequence. The length-n symbol sequence may be an ordered tuple, and the “first-half” may correspond to the first n/2 ordered elements that form the first-half subsequence, and the “second-half” may correspond to the second n/2 ordered elements that form the second-half subsequence. The first term N(n/2, E′) may correspond to the first-half subsequence of the output sequence and the next term N(n/2, E−E′) may correspond to the second-half subsequence of the output sequence.

As an example, for a sequence s=(s₁, s₂, . . . , sₙ), with n being an even integer, the first-half subsequence of s is (s₁, s₂, . . . , sₙ/2), and the second-half subsequence of s is (s_{n/2+1}, s_{n/2+2}, . . . , sₙ).

During the second phase, the transmitting node may determine the total number of symbol sequences over [symbol] ₘ based at least in part on a summation of a product between the first term and the second term, where the first term may be associated with the first half of the length-n symbol sequence and the second term may be associated with the second half of the length-n symbol sequence. The transmitting node may determine E′ based at least in part on AC, and the transition probabilities may be of the form:

$$\frac{N ( \frac{n}{2} , {E}^{′} ) N ( \frac{n}{2} , E - {E}^{′} )}{N ( n , E )} , \qquad ( 10 )$$

where such principle may allow for proceeding hierarchically and considering sequences of lengths n/2, n/4, and so on. When the sequence lengths go down to 1, the transmitting node may determine the actual output symbols by the respective energies.

In some aspects, two special labels l (left) and r (right) may be denoted, where the left label l indicates a sub-subsequence of a given subsequence of the output sequence and the right label r indicates a remaining sub-subsequence of a given subsequence of the output sequence (e.g., a concatenation of the sub-subsequence and the remaining sub-subsequence is the given subsequence). Further, e₀=Ø, where e₀ indicates an initialization as an empty set, and for each t∈{1, . . . , R}, the following may be defined:

$${𝔢}_{t} {=}^{Δ} {\{ 1 , r \}}^{t} = \{ ( 1 , 1 , … , 1 ) , ( 1 , 1 , … , r ) , … , … , ( r , r , … , r ) \} , \qquad ( 11 )$$

where each element of eₜ corresponds to a respective and distinct subsequence of the output sequence and each such subsequence has a length equal to n/2′, and each element of eₜ is of length t. During the second phase, the transmitting node may determine eₜ based at least in part on the left label l and the right label r, where each element of eₜ is of length t, and where t is in a set between 1 and the integer R. Further, for each t, a natural ordering of the elements of eₜ may be assumed. Further, for any e∈eₜ, the one-letter extension of e by l may be denoted by e*l, which may be an element of eₜ₊₁. In other words, when e=(l, r, r), then e*l=(l, r, r, l). The notation e*r may follow a similar definition. For example, when e=(l, r, r), then e*r=(l, r, r, r). When e in eₜ corresponds to a subsequence having length n/2^{t}, then e*l corresponds to a sub-subsequence having length n/2^{t+1}, and e*r corresponds to a remaining sub-subsequence having length n/2^{t+1}.

In some aspects, during an initialization of the second phase, the transmitting node may take as inputs E and x′, as determined from the first phase. During the second phase, the transmitting node may initialize t=0 and

$${E}_{0}^{∅} = E , where {E}_{0}^{∅}$$

indicates the energy of the output sequence (e.g.,

$${E}_{0}^{∅}$$

is equal to E).

In some aspects, during the second phase, the transmitting node may perform multiple iterations from t=0 until (and including) t=R−1. During the second phase, the transmitting node may perform the multiple iterations from the initialization of t=0 to t=R−1, wherein an iteration, of the multiple iterations, may be associated with deriving the energy of the subsequence of the length-n symbol sequence and involves an enumeration of a plurality of elements of eₜ. In each iteration, the transmitting node may enumerate all elements of eₜ according to its natural ordering, where e denotes the element being enumerated. For each

$$ε ∈ \{ 0 , 1 , … , {E}_{t}^{e} \} ,$$

where ε indicates a possible value of an energy of a subsequence of the output sequence and this subsequence has a length of n/2^{t+1}, and

$${E}_{t}^{e}$$

indicates an energy of a subsequence corresponding to label e, the transmitting node may compute transition probabilities in accordance with:

$$\begin{matrix}p ( ε \vert t , {E}_{t}^{e} ) {=}^{Δ} \frac{N ( {2}^{- ( t + 1 )} n , ε ) N ( {2}^{- ( t + 1 )} n , {E}_{t}^{e} - ε )}{N ( {2}^{- t} n , {E}_{t}^{e} )} , \\ where p ( ε \vert t , {E}_{t}^{e} )\end{matrix} \qquad ( 12 )$$

indicates a transition probability. The transmitting node may compute

$$p ( ε \vert t , {E}_{t}^{e} )$$

based at least in part on the number of sequences N, t, ε,

$${E}_{t}^{e} ,$$

and the sequence length n. The transmitting node may determine the number ε*, such that:

$${x}^{′} ∈ [ {\sum }_{ε = 0}^{{ε}^{*} - 1} p ( ε \vert t , {E}_{t}^{e} ) , {\sum }_{ε = 0}^{{ε}^{*}} p ( ε \vert t , {E}_{t}^{e} ) ) , \qquad ( 13 )$$

where ε* indicates an energy level. The transmitting node may determine ε* based at least in part on the scaled dyadic number x′ and a summation involving

$$p ( ε \vert t , {E}_{t}^{e} ) .$$

The transmitting node may update the value of x′ according to:

$${x}^{′} ← \frac{{x}^{′} - {\sum }_{ε = 0}^{{ε}^{*} - 1} p ( ε \vert t , {E}_{t}^{e} )}{p ( {ε}^{*} \vert t , {E}_{t}^{e} )} . \qquad ( 14 )$$

The transmitting node may determine

$${E}_{t + 1}^{e ★ 1} and {E}_{t + 1}^{e ★ r} ,$$

respectively, according to:

$${E}_{t + 1}^{e ★ 1} = {ε}^{*} and {E}_{t + 1}^{e ★ r} = {E}_{t}^{e} - {ε}^{*} , \qquad ( 15 )$$

indicates an energy of a subsequence of the output sequence and corresponds to label e*l, and

$${E}_{t + 1}^{e ⋆ r}$$

indicates an energy of a subsequence of the output sequence and corresponds to label e*r. The transmitting node may determine

$${E}_{t + 1}^{e ⋆ l}$$

based at least in part on ε*, and

$${E}_{t + 1}^{e ⋆ r}$$

based at least in part on

$${E}_{t}^{e}$$

and ε*. After the enumeration of [symbol] ₜ is done, the transmitting node may increase t by 1. In other words, the transmitting node may increase t by 1 after the enumeration of [symbol] ₜ is completed.

In some aspects, during the second phase, the transmitting node may determine output symbols. The transmitting node may assume that t reaches R so that all R−1 iterations have been performed. Further, e₁, e₂, . . . , eₙ may be the enumeration of [symbol] _{R} having size n=2^{R} according to its natural ordering (e.g., [symbol] _{R}={e₁, e₂, . . . , eₙ}), where each element of [symbol] _{R} corresponds to a respective element of the output sequence s. The transmitting node may determine the output sequence s=(s₁, s₂, . . . , sₙ). For each i∈{1, 2, . . . , n}, a unique symbol a∈ [symbol] ₘ may be present, such that

$$E ( a ) = {E}_{R}^{{e}_{i}} , where {E}_{R}^{{e}_{i}}$$

indicates an energy of an i-th symbol of the output sequence. The output sᵢ may then be given by symbol a (e.g., sᵢ=a). In some aspects, the transmitting node determine that the R−1 iterations, associated with the multiple iterations, have been performed. The transmitting node may determine the length-n symbol sequence based at least in part on the unique symbol a in the alphabet [symbol] ₘ such that an energy of the unique symbol a is equal to

$${E}_{R}^{{e}_{i}} ,$$

where an output symbol of the length-n symbol sequence may be given by the unique symbol a.

In some aspects, during the second phase, in a first iteration (e.g., t=0), the transmitting node may determine a first plurality of N sequence quantities. The transmitting node may further compute a first plurality of transition probabilities. Each transition probability of the first plurality of transition probabilities may be proportional to a product of a respective first N sequence quantity (which corresponds to N(n/2, E′), with E′ varying from 0 to E) and a respective second N sequence quantity (which corresponds to N(n/2, E−E′)). The transmitting node may further partition a scaled interval into a first plurality of subintervals. Each subinterval of the first plurality of subintervals may correspond to a respective energy level of a first subsequence of the output sequence (a “first-half” or the left label 1), and each subinterval of the first plurality of subintervals may have a length proportional to a respective transition probability of the first plurality of transition probabilities. In other words, each subinterval of the first plurality of subintervals may have a length proportional to a product of a respective first N sequence quantity and a respective second N sequence quantity, as indicated by Equations (12) and (13).

In some aspects, the transmitting node may identify a first subinterval of the scaled interval based at least in part on x′ and the first plurality of subintervals. The transmitting node may identify a first energy level (ε* for t=0) corresponding to the first subinterval. The first subsequence of the output sequence may have an energy equal to the first energy level, and a first remaining subsequence of the output sequence (a “second-half” or the right label r) may have an energy equal to E minus the first energy level. The transmitting node may further apply a scaling operation on the number x′ in accordance with Equation (14) and a scaling operation on the first subinterval, thereby generating a scaled first subinterval. The transmitting node may determine two numbers

$${E}_{1}^{l} and {E}_{1}^{r} , where {E}_{1}^{l} = {ε}^{*} and {E}_{1}^{r} = {E}_{t}^{e} - {ε}^{*}$$

in accordance with Equation (15). The transmitting node may then increase t by 1. This completes the first iteration.

In some aspects, during the second phase, in a second iteration (e.g., t=1), the transmitting node may determine a second plurality of N sequence quantities. The transmitting node may further compute a second plurality of transition probabilities. Each transition probability of the second plurality of transition probabilities may be proportional to a product of a respective first N sequence quantity (which corresponds to N(n/4, E′), with E′ varying from 0 to

$${E}_{1}^{l} )$$

and a respective second N sequence quantity (which corresponds to

$$N ( n / 4 , {E}_{1}^{l} - {E}^{′} ) ) .$$

The first and second sequence quantities determined during the second iteration may be different from the first and second sequence quantities during the first iteration. The transmitting node may further partition the scaled first subinterval into a second plurality of subintervals. Each subinterval of the second plurality of subintervals may correspond to a respective energy level of a first sub-subsequence of the first subsequence of the output sequence, and each subinterval of the second plurality of subintervals may have a length proportional to a respective transition probability of the second plurality of transition probabilities. In other words, each subinterval of the second plurality of subintervals may have a length proportional to a product of the respective first N sequence quantity and the respective second N sequence quantity.

In some aspects, the transmitting node may identify a second subinterval of the scaled first subinterval based at least in part on x′ and the second plurality of subintervals. The transmitting node may identify a second energy level (denoted by ε*) corresponding to the second subinterval. The first sub-subsequence of the first subsequence of the output sequence has an energy equal to the second energy level, and a first remaining sub-subsequence of the first subsequence of the output sequence has an energy equal to

$${E}_{1}^{l}$$

minus the second energy level. The transmitting node may further apply a scaling operation on the number x′ in accordance with Equation (14) and a scaling operation on the second subinterval, thereby generating a scaled second subinterval. The transmitting node may determine two numbers

$${E}_{2}^{ll} and {E}_{2}^{lr} , where {E}_{2}^{ll} = {E}^{*} and {E}_{2}^{lr} = {E}_{1}^{l} - {ε}^{*}$$

in accordance with Equation (15).

In some aspects, during the second phase, in the second iteration (e.g., t=1), the transmitting node may further determine a third plurality of N sequence quantities. The transmitting node may further compute a third plurality of transition probabilities. Each transition probability of the third plurality of transition probabilities may be proportional to a product of a respective first N sequence quantity (which corresponds to N(n/4, E′), with E′ varying from 0 to

$${E}_{1}^{r} )$$

and a respective second N sequence quantity (which corresponds to

$$N ( n / 4 , {E}_{1}^{r} - {E}^{′} ) ) .$$

The transmitting node may further partition the scaled second subinterval into a third plurality of subintervals. Each subinterval of the third plurality of subintervals may correspond to a respective energy level of a second sub-subsequence of the first remaining subsequence of the output sequence, and each subinterval of the third plurality of subintervals may have a length proportional to a respective transition probability of the third plurality of transition probabilities. In other words, each subinterval of the third plurality of subintervals may have a length proportional to a product of the respective first N sequence quantity and the respective second N sequence quantity. The transmitting node may identify a third subinterval of the scaled second subinterval based at least in part on x′ and the third plurality of subintervals. The transmitting node may identify a third energy level (denoted by ε*) corresponding to the third subinterval. The second sub-subsequence of the first remaining subsequence of the output sequence (the “rl” part) may have an energy equal to the third energy level, and a second remaining sub-subsequence of the first remaining subsequence of the output sequence (the “rr” part) may have an energy equal to

$${E}_{1}^{r}$$

minus the third energy level. The transmitting node may further apply a scaling operation on the number x′ in accordance with Equation (14) and a scaling operation on the third subinterval, thereby generating a scaled third subinterval. The transmitting node may determine two numbers

$${E}_{2}^{rl} and {E}_{2}^{rr} , where {E}_{2}^{rl} = {ε}^{*} and {E}_{2}^{rr} = {E}_{1}^{r} - {ε}^{*}$$

in accordance with Equation (15). The transmitting node may then increase t by 1. This completes the second iteration.

As shown by reference number 706, the transmitting node may perform, to the receiving node, a transmission based at least in part on the length-n symbol sequence. The transmitting node may transmit the length-n symbol sequence to the receiving node. Alternatively, the transmitting node may perform an additional modification to the length-n symbol sequence prior to performing the transmission to the receiving node.

As indicated above, FIG. 7 is provided as an example. Other examples may differ from what is described with regard to FIG. 7.

FIG. 8 is a diagram illustrating an example process 800 performed, for example, by a transmitting node, in accordance with the present disclosure. Example process 800 is an example where the transmitting node (e.g., UE 120 or network node 110) performs operations associated with energy-based arithmetic coding for PAS.

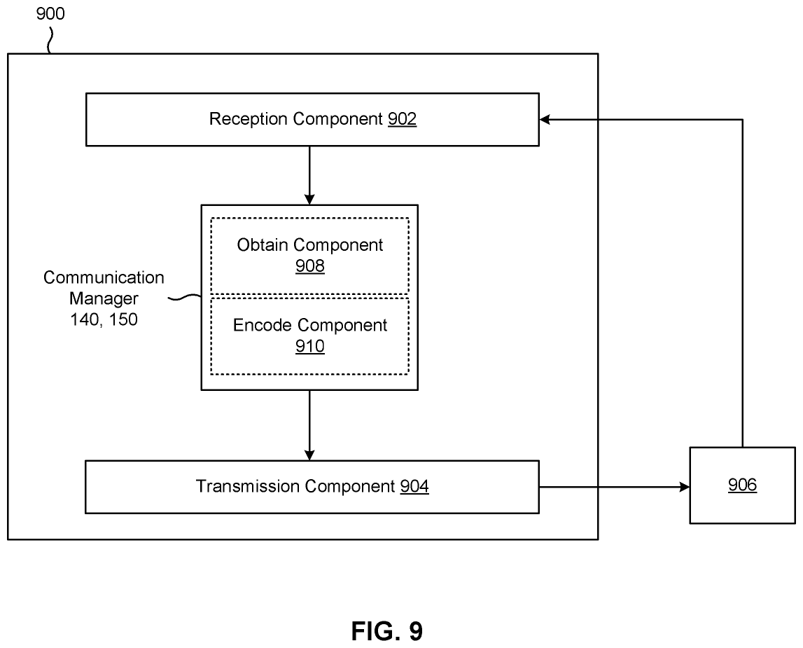

As shown in FIG. 8, in some aspects, process 800 may include obtaining a k-bit sequence of information bits (block 810). For example, the transmitting node (e.g., using communication manager 140, communication manager 150, and/or obtain component 908, depicted in FIG. 9) may obtain a k-bit sequence of information bits, as described above.

As further shown in FIG. 8, in some aspects, process 800 may include encoding the k-bit sequence to an output sequence that corresponds to a length-n symbol sequence in a set of symbol sequences of length n and over an alphabet [symbol] ₘ in accordance with a first phase of energy-based arithmetic coding for PAS and a second phase of energy-based arithmetic coding for PAS, wherein: the first phase of energy-based arithmetic coding for PAS is associated with determining an energy E associated with the length-n symbol sequence; and the second phase of energy-based arithmetic coding for PAS is associated with determining the length-n symbol sequence based at least in part on multiple iterations, wherein each iteration is associated with deriving energies of subsequences of the length-n symbol sequence (block 820). For example, the transmitting node (e.g., using communication manager 140, communication module 150, and/or encode component 910, depicted in FIG. 9) may encode the k-bit sequence to an output sequence that corresponds to a length-n symbol sequence in a set of symbol sequences of length n and over an alphabet [symbol] ₘ in accordance with a first phase of energy-based arithmetic coding for PAS and a second phase of energy-based arithmetic coding for PAS, wherein: the first phase of energy-based arithmetic coding for PAS is associated with determining an energy E associated with the length-n symbol sequence; and the second phase of energy-based arithmetic coding for PAS is associated with determining the length-n symbol sequence based at least in part on multiple iterations, wherein each iteration is associated with deriving energies of subsequences of the length-n symbol sequence, as described above.

As further shown in FIG. 8, in some aspects, process 800 may include performing, to a receiving node, a transmission based at least in part on the length-n symbol sequence (block 830). For example, the transmitting node (e.g., using communication manager 140, communication module 150, and/or transmission component 904, depicted in FIG. 9) may perform, to a receiving node, a transmission based at least in part on the length-n symbol sequence, as described above.

Process 800 may include additional aspects, such as any single aspect or any combination of aspects described below and/or in connection with one or more other processes described elsewhere herein.

In a first aspect, the first phase of energy-based arithmetic coding for PAS further comprises determining a plurality of cumulative sequence quantities, wherein each cumulative sequence quantity of the plurality of cumulative sequence quantities represent a total number associated with a set of symbol sequences of length n and over the alphabet [symbol] ₘ and having an energy below or equal to a respective energy level.

In a second aspect, alone or in combination with the first aspect, the first phase of energy-based arithmetic coding for PAS further comprises partitioning an interval into a plurality of subintervals based at least in part on the plurality of cumulative sequence quantities, wherein each subinterval of the plurality of subintervals corresponds to a respective energy level, wherein each subinterval of the plurality of subintervals has a length proportional to a respective sequence quantity, and wherein the respective sequence quantity represents a number associated with a set of symbol sequences of length n and over the alphabet [symbol] ₘ and having an energy equal to the respective energy level.

In a third aspect, alone or in combination with one or more of the first and second aspects, the first phase of energy-based arithmetic coding for PAS further comprises selecting the energy E based at least in part on the k-bit sequence of information bits and the plurality of subintervals, wherein the output sequence determined at an end of the second phase of energy-based arithmetic coding for probabilistic amplitude shaping is associated with an energy that is equal to the energy E.

In a fourth aspect, alone or in combination with one or more of the first through third aspects, the second phase of energy-based arithmetic coding for PAS further comprises initiating a first iteration of the second phase of energy-based arithmetic coding for PAS, determining a first plurality of sequence quantities, computing a first plurality of transition probabilities, wherein each transition probability of the first plurality of transition probabilities is proportional to a product of a respective first sequence quantity and a respective second sequence quantity, of the first plurality of sequence quantities, and partitioning a scaled interval into a first plurality of subintervals, wherein each interval of the first plurality of subintervals corresponds to a respective energy level of a first subsequence of the output sequence, wherein each subinterval of the first plurality of subintervals has a length proportional to a respective transition probability of the first plurality of transition probabilities, and wherein each subinterval of the first plurality of subintervals has a length proportional to a product of the respective first sequence quantity and the respective second sequence quantity.

In a fifth aspect, alone or in combination with one or more of the first through fourth aspects, the second phase of energy-based arithmetic coding for PAS further comprises identifying a first subinterval of the scaled interval based at least in part on a scaled dyadic number x′ and the first plurality of subintervals, identifying a first energy level corresponding to the first subinterval, determining the first subsequence of the output sequence to have an energy equal to the first energy level, and a first remaining subsequence of the output sequence has an energy equal to the energy E minus the first energy level, applying a scaling operation on the scaled dyadic number x′ and a scaling operation on the first subinterval, thereby generating a scaled first subinterval, and completing the first iteration.

In a sixth aspect, alone or in combination with one or more of the first through fifth aspects, the second phase of energy-based arithmetic coding for PAS further comprises initiating a second iteration of the second phase of energy-based arithmetic coding for PAS, determining a second plurality of sequence quantities, computing a second plurality of transition probabilities, wherein each transition probability of the second plurality of transition probabilities is proportional to a product of a respective first sequence quantity and a respective second sequence quantity, of the second plurality of sequence quantities, and partitioning a scaled first subinterval into a second plurality of subintervals, wherein each interval of the second plurality of subintervals corresponds to a respective energy level of a first sub-subsequence of the first subsequence of the output sequence, wherein each subinterval of the second plurality of subintervals has a length proportional to a respective transition probability of the second plurality of transition probabilities, and wherein each subinterval of the second plurality of subintervals has a length proportional to a product of a respective first sequence quantity and a respective second sequence quantity.

In a seventh aspect, alone or in combination with one or more of the first through sixth aspects, the second phase of energy-based arithmetic coding for PAS further comprises identifying a second subinterval of the scaled first interval based at least in part on a scaled dyadic number x′ and the second plurality of subintervals, identifying a second energy level corresponding to the second subinterval, determining the first sub-subsequence of the first subsequence of the output sequence to have an energy equal to the second energy level, and a first remaining sub-subsequence of the first subsequence of the output sequence has an energy equal to the energy of the first subsequence minus the second energy level, applying a scaling operation on the scaled dyadic number x′ and a scaling operation on the second subinterval, thereby generating a scaled second subinterval.

In an eighth aspect, alone or in combination with one or more of the first through seventh aspects, the second phase of energy-based arithmetic coding for PAS further comprises determining, during the second iteration of the second phase of energy-based arithmetic coding for PAS, a third plurality of sequence quantities, computing a third plurality of transition probabilities, wherein each transition probability of the third plurality of transition probabilities is proportional to a product of a respective first sequence quantity and a respective second sequence quantity, of the third plurality of sequence quantities, and partitioning a scaled second subinterval into a third plurality of subintervals, wherein each interval of the third plurality of subintervals corresponds to a respective energy level of a second sub-subsequence of a first remaining subsequence of the output sequence, wherein each subinterval of the third plurality of subintervals has a length proportional to a respective transition probability of the third plurality of transition probabilities, and wherein each subinterval of the third plurality of subintervals has a length proportional to a product of a respective first sequence quantity and a respective second sequence quantity.

In a ninth aspect, alone or in combination with one or more of the first through eighth aspects, the second phase of energy-based arithmetic coding for PAS further comprises identifying a third subinterval of the scaled second interval based at least in part on a scaled dyadic number x′ and the third plurality of subintervals, identifying a third energy level corresponding to the third subinterval, determining the second sub-subsequence of the first remaining subsequence of the output sequence to have an energy equal to the third energy level, and a second remaining sub-subsequence of the first remaining subsequence of the output sequence has an energy equal to the energy of the first remaining subsequence minus the third energy level, applying a scaling operation on the scaled dyadic number x′ and a scaling operation on the second subinterval, thereby generating a scaled second subinterval, and completing the second iteration.

Although FIG. 8 shows example blocks of process 800, in some aspects, process 800 may include additional blocks, fewer blocks, different blocks, or differently arranged blocks than those depicted in FIG. 8. Additionally, or alternatively, two or more of the blocks of process 800 may be performed in parallel.

FIG. 9 is a diagram of an example apparatus 900 for wireless communication, in accordance with the present disclosure. The apparatus 900 may be a transmitting node, or a transmitting node may include the apparatus 900. In some aspects, the apparatus 900 includes a reception component 902 and a transmission component 904, which may be in communication with one another (for example, via one or more buses and/or one or more other components). As shown, the apparatus 900 may communicate with another apparatus 906 (such as a UE, a base station, or another wireless communication device) using the reception component 902 and the transmission component 904. As further shown, the apparatus 900 may include the communication manager 140, 150. The communication manager 140, 150 may include one or more of an obtain component 908, or an encode component 910, among other examples.

In some aspects, the apparatus 900 may be configured to perform one or more operations described herein in connection with FIG. 7. Additionally, or alternatively, the apparatus 900 may be configured to perform one or more processes described herein, such as process 800 of FIG. 8. In some aspects, the apparatus 900 and/or one or more components shown in FIG. 9 may include one or more components of the transmitting node described in connection with FIG. 2. Additionally, or alternatively, one or more components shown in FIG. 9 may be implemented within one or more components described in connection with FIG. 2. Additionally, or alternatively, one or more components of the set of components may be implemented at least in part as software stored in a memory. For example, a component (or a portion of a component) may be implemented as instructions or code stored in a non-transitory computer-readable medium and executable by a controller or a processor to perform the functions or operations of the component.

The reception component 902 may receive communications, such as reference signals, control information, data communications, or a combination thereof, from the apparatus 906. The reception component 902 may provide received communications to one or more other components of the apparatus 900. In some aspects, the reception component 902 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components of the apparatus 900. In some aspects, the reception component 902 may include one or more antennas, a modem, a demodulator, a MIMO detector, a receive processor, a controller/processor, a memory, or a combination thereof, of the transmitting node described in connection with FIG. 2.

The transmission component 904 may transmit communications, such as reference signals, control information, data communications, or a combination thereof, to the apparatus 906. In some aspects, one or more other components of the apparatus 900 may generate communications and may provide the generated communications to the transmission component 904 for transmission to the apparatus 906. In some aspects, the transmission component 904 may perform signal processing on the generated communications (such as filtering, amplification, modulation, digital-to-analog conversion, multiplexing, interleaving, mapping, or encoding, among other examples), and may transmit the processed signals to the apparatus 906. In some aspects, the transmission component 904 may include one or more antennas, a modem, a modulator, a transmit MIMO processor, a transmit processor, a controller/processor, a memory, or a combination thereof, of the transmitting node described in connection with FIG. 2. In some aspects, the transmission component 904 may be co-located with the reception component 902 in a transceiver.

The obtain component 908 may obtain a k-bit sequence of information bits. The encode component 910 may encode the k-bit sequence to an output sequence that corresponds to a length-n symbol sequence in a set of symbol sequences of length n and over an alphabet [symbol] ₘ in accordance with a first phase of energy-based arithmetic coding for probabilistic amplitude shaping (PAS) and a second phase of energy-based arithmetic coding for PAS, wherein: the first phase of energy-based arithmetic coding for PAS is associated with determining an energy E associated with the length-n symbol sequence; and the second phase of energy-based arithmetic coding for PAS is associated with determining the length-n symbol sequence based at least in part on multiple iterations, wherein each iteration is associated with deriving energies of subsequences of the length-n symbol sequence. The transmission component 904 may perform, to a receiving node, a transmission based at least in part on the length-n symbol sequence.

The number and arrangement of components shown in FIG. 9 are provided as an example. In practice, there may be additional components, fewer components, different components, or differently arranged components than those shown in FIG. 9. Furthermore, two or more components shown in FIG. 9 may be implemented within a single component, or a single component shown in FIG. 9 may be implemented as multiple, distributed components. Additionally, or alternatively, a set of (one or more) components shown in FIG. 9 may perform one or more functions described as being performed by another set of components shown in FIG. 9.

The following provides an overview of some Aspects of the present disclosure:

Aspect 1: A method of wireless communication performed by a transmitting node, comprising: obtaining a k-bit sequence of information bits; encoding the k-bit sequence to an output sequence that corresponds to a length-n symbol sequence in a set of symbol sequences of length n and over an alphabet [symbol] ₘ in accordance with a first phase of energy-based arithmetic coding for probabilistic amplitude shaping (PAS) and a second phase of energy-based arithmetic coding for PAS, wherein: the first phase of energy-based arithmetic coding for PAS is associated with determining an energy E associated with the length-n symbol sequence; and the second phase of energy-based arithmetic coding for PAS is associated with determining the length-n symbol sequence based at least in part on multiple iterations, wherein each iteration is associated with deriving energies of subsequences of the length-n symbol sequence; and performing, to a receiving node, a transmission based at least in part on the length-n symbol sequence.

Aspect 2: The method of Aspect 1, wherein the first phase of energy-based arithmetic coding for PAS further comprises: determining a plurality of cumulative sequence quantities, wherein each cumulative sequence quantity of the plurality of cumulative sequence quantities represent a total number associated with a set of symbol sequences of length n and over the alphabet [symbol] ₘ and having an energy below or equal to a respective energy level.

Aspect 3: The method of Aspect 2, wherein the first phase of energy-based arithmetic coding for PAS further comprises: partitioning an interval into a plurality of subintervals based at least in part on the plurality of cumulative sequence quantities, wherein each subinterval of the plurality of subintervals corresponds to a respective energy level, wherein each subinterval of the plurality of subintervals has a length proportional to a respective sequence quantity, and wherein the respective sequence quantity represents a number associated with a set of symbol sequences of length n and over the alphabet [symbol] ₘ and having an energy equal to the respective energy level.

Aspect 4: The method of Aspect 3, wherein the first phase of energy-based arithmetic coding for PAS further comprises: selecting the energy E based at least in part on the k-bit sequence of information bits and the plurality of subintervals, wherein the output sequence determined at an end of the second phase of energy-based arithmetic coding for probabilistic amplitude shaping is associated with an energy that is equal to the energy E.

Aspect 5: The method of any of Aspects 1-4, wherein the second phase of energy-based arithmetic coding for PAS further comprises: initiating a first iteration of the second phase of energy-based arithmetic coding for PAS; determining a first plurality of sequence quantities; computing a first plurality of transition probabilities, wherein each transition probability of the first plurality of transition probabilities is proportional to a product of a respective first sequence quantity and a respective second sequence quantity, of the first plurality of sequence quantities; and partitioning a scaled interval into a first plurality of subintervals, wherein each interval of the first plurality of subintervals corresponds to a respective energy level of a first subsequence of the output sequence, wherein each subinterval of the first plurality of subintervals has a length proportional to a respective transition probability of the first plurality of transition probabilities, and wherein each subinterval of the first plurality of subintervals has a length proportional to a product of the respective first sequence quantity and the respective second sequence quantity.

Aspect 6: The method of Aspect 5, wherein the second phase of energy-based arithmetic coding for PAS further comprises: identifying a first subinterval of the scaled interval based at least in part on a scaled dyadic number x′ and the first plurality of subintervals; identifying a first energy level corresponding to the first subinterval; determining the first subsequence of the output sequence to have an energy equal to the first energy level, and a first remaining subsequence of the output sequence has an energy equal to the energy E minus the first energy level; applying a scaling operation on the scaled dyadic number x′ and a scaling operation on the first subinterval, thereby generating a scaled first subinterval; and completing the first iteration.

Aspect 7: The method of Aspect 6, wherein the second phase of energy-based arithmetic coding for PAS further comprises: initiating a second iteration of the second phase of energy-based arithmetic coding for PAS; determining a second plurality of sequence quantities; computing a second plurality of transition probabilities, wherein each transition probability of the second plurality of transition probabilities is proportional to a product of a respective first sequence quantity and a respective second sequence quantity, of the second plurality of sequence quantities; and partitioning a scaled first subinterval into a second plurality of subintervals, wherein each interval of the second plurality of subintervals corresponds to a respective energy level of a first sub-subsequence of the first subsequence of the output sequence, wherein each subinterval of the second plurality of subintervals has a length proportional to a respective transition probability of the second plurality of transition probabilities, and wherein each subinterval of the second plurality of subintervals has a length proportional to a product of a respective first sequence quantity and a respective second sequence quantity.

Aspect 8: The method of Aspect 7, wherein the second phase of energy-based arithmetic coding for PAS further comprises: identifying a second subinterval of the scaled first interval based at least in part on a scaled dyadic number x′ and the second plurality of subintervals; identifying a second energy level corresponding to the second subinterval; determining the first sub-subsequence of the first subsequence of the output sequence to have an energy equal to the second energy level, and a first remaining sub-subsequence of the first subsequence of the output sequence has an energy equal to the energy of the first subsequence minus the second energy level; applying a scaling operation on the scaled dyadic number x′ and a scaling operation on the second subinterval, thereby generating a scaled second subinterval.

Aspect 9: The method of Aspect 8, wherein the second phase of energy-based arithmetic coding for PAS further comprises: determining, during the second iteration of the second phase of energy-based arithmetic coding for PAS, a third plurality of sequence quantities; computing a third plurality of transition probabilities, wherein each transition probability of the third plurality of transition probabilities is proportional to a product of a respective first sequence quantity and a respective second sequence quantity, of the third plurality of sequence quantities; and partitioning a scaled second subinterval into a third plurality of subintervals, wherein each interval of the third plurality of subintervals corresponds to a respective energy level of a second sub-subsequence of a first remaining subsequence of the output sequence, wherein each subinterval of the third plurality of subintervals has a length proportional to a respective transition probability of the third plurality of transition probabilities, and wherein each subinterval of the third plurality of subintervals has a length proportional to a product of a respective first sequence quantity and a respective second sequence quantity.

Aspect 10: The method of Aspect 9, wherein the second phase of energy-based arithmetic coding for PAS further comprises: identifying a third subinterval of the scaled second interval based at least in part on a scaled dyadic number x′ and the third plurality of subintervals; identifying a third energy level corresponding to the third subinterval; determining the second sub-subsequence of the first remaining subsequence of the output sequence to have an energy equal to the third energy level, and a second remaining sub-subsequence of the first remaining subsequence of the output sequence has an energy equal to the energy of the first remaining subsequence minus the third energy level; applying a scaling operation on the scaled dyadic number x′ and a scaling operation on the second subinterval, thereby generating a scaled second subinterval; and completing the second iteration.

Aspect 11: An apparatus for wireless communication at a device, comprising a processor; memory coupled with the processor; and instructions stored in the memory and executable by the processor to cause the apparatus to perform the method of one or more of Aspects 1-10.

Aspect 12: A device for wireless communication, comprising a memory and one or more processors coupled to the memory, the one or more processors configured to perform the method of one or more of Aspects 1-10.

Aspect 13: An apparatus for wireless communication, comprising at least one means for performing the method of one or more of Aspects 1-10.

Aspect 14: A non-transitory computer-readable medium storing code for wireless communication, the code comprising instructions executable by a processor to perform the method of one or more of Aspects 1-10.

Aspect 15: A non-transitory computer-readable medium storing a set of instructions for wireless communication, the set of instructions comprising one or more instructions that, when executed by one or more processors of a device, cause the device to perform the method of one or more of Aspects 1-10.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

1. An apparatus for wireless communication at a transmitting node, comprising:
a memory; and
one or more processors, coupled to the memory, configured to:
obtain a k-bit sequence of information bits;
encode the k-bit sequence to an output sequence that corresponds to a length-n symbol sequence in a set of symbol sequences of length n and over an alphabet in accordance with a first phase of energy-based arithmetic coding for probabilistic amplitude shaping (PAS) and a second phase of energy-based arithmetic coding for PAS, wherein:
the first phase of energy-based arithmetic coding for PAS is associated with determining an energy E associated with the length-n symbol sequence; and
the second phase of energy-based arithmetic coding for PAS is associated with determining the length-n symbol sequence based at least in part on multiple iterations, wherein each iteration is associated with deriving energies of subsequences of the length-n symbol sequence; and
perform, to a receiving node, a transmission based at least in part on the length-n symbol sequence.

2. The apparatus of claim 1, wherein the one or more processors, during the first phase of energy-based arithmetic coding for PAS, are configured to:
determine a plurality of cumulative sequence quantities, wherein each cumulative sequence quantity of the plurality of cumulative sequence quantities represent a total number associated with a set of symbol sequences of length n and over the alphabet and having an energy below or equal to a respective energy level.

3. The apparatus of claim 2, wherein the one or more processors, during the first phase of energy-based arithmetic coding for PAS, are configured to:
partition an interval into a plurality of subintervals based at least in part on the plurality of cumulative sequence quantities, wherein each subinterval of the plurality of subintervals corresponds to a respective energy level, wherein each subinterval of the plurality of subintervals has a length proportional to a respective sequence quantity, and wherein the respective sequence quantity represents a number associated with a set of symbol sequences of length n and over the alphabet and having an energy equal to the respective energy level.

4. The apparatus of claim 3, wherein the one or more processors, during the first phase of energy-based arithmetic coding for PAS, are configured to:
select the energy E based at least in part on the k-bit sequence of information bits and the plurality of subintervals, wherein the output sequence determined at an end of the second phase of energy-based arithmetic coding for probabilistic amplitude shaping is associated with an energy that is equal to the energy E.

5. The apparatus of claim 1, wherein the one or more processors, during the second phase of energy-based arithmetic coding for PAS, are configured to:
initiate a first iteration of the second phase of energy-based arithmetic coding for PAS; determine a first plurality of sequence quantities;
compute a first plurality of transition probabilities, wherein each transition probability of the first plurality of transition probabilities is proportional to a product of a respective first sequence quantity and a respective second sequence quantity, of the first plurality of sequence quantities; and
partition a scaled interval into a first plurality of subintervals, wherein each interval of the first plurality of subintervals corresponds to a respective energy level of a first subsequence of the output sequence, wherein each subinterval of the first plurality of subintervals has a length proportional to a respective transition probability of the first plurality of transition probabilities, and wherein each subinterval of the first plurality of subintervals has a length proportional to a product of the respective first sequence quantity and the respective second sequence quantity.

6. The apparatus of claim 5, wherein the one or more processors, during the second phase of energy-based arithmetic coding for PAS, are configured to:
identify a first subinterval of the scaled interval based at least in part on a scaled dyadic number x′ and the first plurality of subintervals;
identify a first energy level corresponding to the first subinterval;
determine the first subsequence of the output sequence to have an energy equal to the first energy level, and a first remaining subsequence of the output sequence has an energy equal to the energy E minus the first energy level;
apply a scaling operation on the scaled dyadic number x′ and a scaling operation on the first subinterval, thereby generating a scaled first subinterval; and
complete the first iteration.

7. The apparatus of claim 6, wherein the one or more processors, during the second phase of energy-based arithmetic coding for PAS, are configured to:
initiate a second iteration of the second phase of energy-based arithmetic coding for PAS; determine a second plurality of sequence quantities;
compute a second plurality of transition probabilities, wherein each transition probability of the second plurality of transition probabilities is proportional to a product of a respective first sequence quantity and a respective second sequence quantity, of the second plurality of sequence quantities; and
partition a scaled first subinterval into a second plurality of subintervals, wherein each interval of the second plurality of subintervals corresponds to a respective energy level of a first sub-subsequence of the first subsequence of the output sequence, wherein each subinterval of the second plurality of subintervals has a length proportional to a respective transition probability of the second plurality of transition probabilities, and wherein each subinterval of the second plurality of subintervals has a length proportional to a product of a respective first sequence quantity and a respective second sequence quantity.

8. The apparatus of claim 7, wherein the one or more processors, during the second phase of energy-based arithmetic coding for PAS, are configured to:
identify a second subinterval of the scaled first interval based at least in part on a scaled dyadic number x′ and the second plurality of subintervals;
identify a second energy level corresponding to the second subinterval;
determine the first sub-subsequence of the first subsequence of the output sequence to have an energy equal to the second energy level, and a first remaining sub-subsequence of the first subsequence of the output sequence has an energy equal to the energy of the first subsequence minus the second energy level;
apply a scaling operation on the scaled dyadic number x′ and a scaling operation on the second subinterval, thereby generating a scaled second subinterval.

9. The apparatus of claim 8, wherein the one or more processors, during the second phase of energy-based arithmetic coding for PAS, are configured to:
determine, during the second iteration of the second phase of energy-based arithmetic coding for PAS, a third plurality of sequence quantities;
compute a third plurality of transition probabilities, wherein each transition probability of the third plurality of transition probabilities is proportional to a product of a respective first sequence quantity and a respective second sequence quantity, of the third plurality of sequence quantities; and
partition a scaled second subinterval into a third plurality of subintervals, wherein each interval of the third plurality of subintervals corresponds to a respective energy level of a second sub-subsequence of a first remaining subsequence of the output sequence, wherein each subinterval of the third plurality of subintervals has a length proportional to a respective transition probability of the third plurality of transition probabilities, and wherein each subinterval of the third plurality of subintervals has a length proportional to a product of a respective first sequence quantity and a respective second sequence quantity.

10. The apparatus of claim 9, wherein the one or more processors, during the second phase of energy-based arithmetic coding for PAS, are configured to:
identify a third subinterval of the scaled second interval based at least in part on a scaled dyadic number x′ and the third plurality of subintervals;
identify a third energy level corresponding to the third subinterval;
determine the second sub-subsequence of the first remaining subsequence of the output sequence to have an energy equal to the third energy level, and a second remaining sub-subsequence of the first remaining subsequence of the output sequence has an energy equal to the energy of the first remaining subsequence minus the third energy level;
apply a scaling operation on the scaled dyadic number x′ and a scaling operation on the second subinterval, thereby generating a scaled second subinterval; and
complete the second iteration.

11. A method of wireless communication performed by a transmitting node, comprising:
obtaining a k-bit sequence of information bits;
encoding the k-bit sequence to an output sequence that corresponds to a length-nsymbol sequence in a set of symbol sequences of length n and over an alphabet in accordance with a first phase of energy-based arithmetic coding for probabilistic amplitude shaping (PAS) and a second phase of energy-based arithmetic coding for PAS, wherein:
the first phase of energy-based arithmetic coding for PAS is associated with determining an energy E associated with the length-n symbol sequence; and
the second phase of energy-based arithmetic coding for PAS is associated with determining the length-n symbol sequence based at least in part on multiple iterations, wherein each iteration is associated with deriving energies of subsequences of the length-n symbol sequence; and
performing, to a receiving node, a transmission based at least in part on the length-n symbol sequence.

12. The method of claim 11, wherein the first phase of energy-based arithmetic coding for PAS further comprises:
determining a plurality of cumulative sequence quantities, wherein each cumulative sequence quantity of the plurality of cumulative sequence quantities represent a total number associated with a set of symbol sequences of length n and over the alphabet and having an energy below or equal to a respective energy level.

13. The method of claim 12, wherein the first phase of energy-based arithmetic coding for PAS further comprises:
partitioning an interval into a plurality of subintervals based at least in part on the plurality of cumulative sequence quantities, wherein each subinterval of the plurality of subintervals corresponds to a respective energy level, wherein each subinterval of the plurality of subintervals has a length proportional to a respective sequence quantity, and wherein the respective sequence quantity represents a number associated with a set of symbol sequences of length n and over the alphabet and having an energy equal to the respective energy level.

14. The method of claim 13, wherein the first phase of energy-based arithmetic coding for PAS further comprises:
selecting the energy E based at least in part on the k-bit sequence of information bits and the plurality of subintervals, wherein the output sequence determined at an end of the second phase of energy-based arithmetic coding for probabilistic amplitude shaping is associated with an energy that is equal to the energy E.

15. The method of claim 11, wherein the second phase of energy-based arithmetic coding for PAS further comprises:
initiating a first iteration of the second phase of energy-based arithmetic coding for PAS;
determining a first plurality of sequence quantities;
computing a first plurality of transition probabilities, wherein each transition probability of the first plurality of transition probabilities is proportional to a product of a respective first sequence quantity and a respective second sequence quantity, of the first plurality of sequence quantities; and
partitioning a scaled interval into a first plurality of subintervals, wherein each interval of the first plurality of subintervals corresponds to a respective energy level of a first subsequence of the output sequence, wherein each subinterval of the first plurality of subintervals has a length proportional to a respective transition probability of the first plurality of transition probabilities, and wherein each subinterval of the first plurality of subintervals has a length proportional to a product of the respective first sequence quantity and the respective second sequence quantity.

16. The method of claim 15, wherein the second phase of energy-based arithmetic coding for PAS further comprises:
identifying a first subinterval of the scaled interval based at least in part on a scaled dyadic number x′ and the first plurality of subintervals;
identifying a first energy level corresponding to the first subinterval;
determining the first subsequence of the output sequence to have an energy equal to the first energy level, and a first remaining subsequence of the output sequence has an energy equal to the energy E minus the first energy level;
applying a scaling operation on the scaled dyadic number x′ and a scaling operation on the first subinterval, thereby generating a scaled first subinterval; and
completing the first iteration.

17. The method of claim 16, wherein the second phase of energy-based arithmetic coding for PAS further comprises:
initiating a second iteration of the second phase of energy-based arithmetic coding for PAS; determining a second plurality of sequence quantities;
computing a second plurality of transition probabilities, wherein each transition probability of the second plurality of transition probabilities is proportional to a product of a respective first sequence quantity and a respective second sequence quantity, of the second plurality of sequence quantities; and
partitioning a scaled first subinterval into a second plurality of subintervals, wherein each interval of the second plurality of subintervals corresponds to a respective energy level of a first sub-subsequence of the first subsequence of the output sequence, wherein each subinterval of the second plurality of subintervals has a length proportional to a respective transition probability of the second plurality of transition probabilities, and wherein each subinterval of the second plurality of subintervals has a length proportional to a product of a respective first sequence quantity and a respective second sequence quantity.

18. The method of claim 17, wherein the second phase of energy-based arithmetic coding for PAS further comprises:
identifying a second subinterval of the scaled first interval based at least in part on a scaled dyadic number x′ and the second plurality of subintervals;
identifying a second energy level corresponding to the second subinterval;
determining the first sub-subsequence of the first subsequence of the output sequence to have an energy equal to the second energy level, and a first remaining sub-subsequence of the first subsequence of the output sequence has an energy equal to the energy of the first subsequence minus the second energy level;
applying a scaling operation on the scaled dyadic number x′ and a scaling operation on the second subinterval, thereby generating a scaled second subinterval.

19. The method of claim 18, wherein the second phase of energy-based arithmetic coding for PAS further comprises:
determining, during the second iteration of the second phase of energy-based arithmetic coding for PAS, a third plurality of sequence quantities;
computing a third plurality of transition probabilities, wherein each transition probability of the third plurality of transition probabilities is proportional to a product of a respective first sequence quantity and a respective second sequence quantity, of the third plurality of sequence quantities; and
partitioning a scaled second subinterval into a third plurality of subintervals, wherein each interval of the third plurality of subintervals corresponds to a respective energy level of a second sub-subsequence of a first remaining subsequence of the output sequence, wherein each subinterval of the third plurality of subintervals has a length proportional to a respective transition probability of the third plurality of transition probabilities, and wherein each subinterval of the third plurality of subintervals has a length proportional to a product of a respective first sequence quantity and a respective second sequence quantity.

20-30. (canceled)
